(19) United States
(12) Patent Application Publication
(10) Pub. No.: US 2004/0221886 A1
(43) Pub. Date: Nov. 11, 2004

(54) Solar cell module and solar cell array using same

(75) Inventor: Toshiaki Oono, Yohkaichi-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 10/788,025

(22) Filed: Feb. 26, 2004

(30) Foreign Application Priority Data
Feb. 26, 2003 (JP) 2003-050055
Mar. 25, 2003 (JP) 2003-083779

(51) Int. Cl. H01L 31/00

(52) U.S. Cl. 136/251; 136/244; 136/291

(57) ABSTRACT

In the solar cell module, a plate-like main body having a power generating function has two end portions opposed to each other, an eaves side frame is provided at one end portion thereof, and a ridge side frame is provided at another end portion thereof, a frame cover capable of being brought into contact with a ridge side frame of another solar cell module is attachably and detachably attached to the eaves side frame, the eaves side frame is provided with an engaging member which engages with the frame cover, and the frame cover is provided with an engaging member which engages with the engaging member on the eaves side frame and an elastic member brought into contact with the engaging member on the eaves side frame to press.

### BACKGROUND OF THE INVENTION

1. Field of the Invention

The present invention relates to a solar cell module generating power by utilizing solar energy, and a solar cell array constituted by installing a plurality of solar cell modules above a roof of a building and overlapping the solar cell modules in such a manner that a ridge side end portion of an eaves side solar cell module is arranged below an eaves side end portion of a ridge side solar cell module.

2. Description of the Related Art

As shown in, for example, FIG. 32, there is conventionally known a solar power generating roof 400 constituted by arranging to overlap tile integrated type solar cell modules 30 for converting solar energy into electric energy on a roof of a house in such a manner that a ridge side end portion of an eaves side solar cell module is arranged below an eaves side end portion of a ridge side solar cell module in order to reduce a household electric load.

In the case of the tile type solar power generating roof 400, as shown in FIG. 33, there is used the solar cell module 30 in which a solar cell 32 constituted by attaching together a plurality of solar cell elements to a light transmitting board of glass, resin or the like is embedded to an upper portion of a tile-like main body 31 formed in substantially the same shape as that of a tile 10 and the tile-like main body 31 and the solar cell 32 are integrated by an adhering agent of a resin or the like. The solar cell module 30 is not different at all from the tile 10 which is not provided with the solar cell 32 in shape thereof and therefore, in arranging the solar cell module 30, similar to construction of the ordinary tile 10, the tiles 10 can be overlapped successively on a roof of a house on a cross piece 9 arranged above a roof board 33 from an eaves side of the roof in such a manner that a ridge side end portion of an eaves side tile is arranged below an eaves side end portion of a ridge side tile. Further, it is general to pass an output wiring 34 outputted from the solar cell module 30 through a clearance between the tile 10 and the roof board 33 produced by overlapping the tiles 10.

Further, as shown in FIG. 34A, in two of the tiles 10 contiguous to each other in a direction in parallel with a ridge of the roof, that is, in a horizontal direction in parallel with a roof face, the tiles 10 are brought in mesh with each other by an upper projected portion 35 formed at one tile 10 and projected downwardly and a lower projected portion 36 formed at another tile 10 and projected upwardly to thereby prevent the tiles 10 from easily shifting from each other.

Further, as shown in FIGS. 34B, there is a case of arranging a flat plate tile 27 or a wavy plate tile 28 having a snow guard provided with a projection 29 for snow guard projected upwardly for preventing fallen snow from being dropped at the tile 10 arranged at an eaves side vicinity of a house.

However, it is necessary to carry out wiring by fixing the tile 10 while being partially overlapped on the roof face as described above and therefore, when all of the wiring operation has been finished, there is brought about a state in which wirings of the solar cell modules as well as fixing the solar cell modules on the roof face have been finished.

Therefore, when it is necessary to carry out operation of removing the solar cell module from the roof face at a later stage by wrong wiring or the like, the operation becomes complicated and problematic.

Further, even in operation of maintenance and check of the solar cell module or the like, when the operation needs to remove the solar cell module, the operation is not easy.

Further, when the projection for snow guard is provided at the tile integrated type solar cell module as described above, not only a light receiving area (power generating area) of the solar cell module is reduced but also a problem that shadow is made by the projection is posed. Further, when the ordinary tile 10 having the snow guard is used in order to resolve the problem, not only construction is complicated but also at a surrounding of the snow guard portion, the weight is increased by dammed snow and therefore, the tile needs to be provided with strength bearable to the load and further, two kinds of the tiles 10 of the tile 10 with the snow guard and the general tile 10 need to prepare and in fabrication and construction, the steps are complicated and problematic.

Although as a system of snow guard and wiring, there has been proposed a solar cell integrated type roof member (refer to, for example, Japanese Unexamined Patent Publication JP-A 2000-199302) providing a projected portion on the surface and using the projected portion as a portion for containing a snow guard and a terminal taking out portion or a method of providing a snow guard on a surface of a solar cell integrated type roof member or the like (refer to, for example, Japanese Unexamined Patent Publication JP-A 2000-336874), the above-described problem cannot be resolved.

Further, in the case of a tile type solar power generating roof 401 shown in FIG. 35, a solar cell module 130 is constituted by attaching a frame 108 of a metal or the like having an attaching structure/waterproof structure which can be substituted for a tile 110 to a solar cell 132 constituted by attaching together solar cell elements to a light transmitting board of glass, resin or the like and the solar cell module 130 can be laid mixedly with other tile 110 which is not provided with the solar cell.

However, when the solar cell module 130 is laid in a tile-like shape as described above, a clearance produced by overlapping the modules is smaller and ventilating performance thereof is poorer than those in the case of using a general tile. Particularly when the frame 108 is made of a metal fabricated by extrusion molding or the like, it is difficult to exhaust humidity by blowing rain water or dew condensation and heat stored on the rear side of the tile in summer time or the like. Further, there poses a problem of noise by creaking at overlapped portions of the tile 110 and the solar cell module 130 and the solar cell modules 130 and wear of a coating a rail member thereby. Further, there poses a problem that when the solar cell modules 130 are installed as in overlapping tiles, in the case of interchanging the solar cell module by maintenance or the like, attachment and detachment of the module become complicated.

Meanwhile, as shown in FIG. 36, as a method of preventing rain water from blowing in, there has been proposed to sandwich a synthetic resin foam member between a ridge side frame 126 of a lower stage solar cell module and an eaves side frame 127 of an upper stage module (refer to, for example, Japanese Unexamined Patent Publication JP-A 2002-61356).

Further, as a method of ventilating the rear face of the tile, there has been proposed a method of opening a slit at the eaves side frame 127 (refer to, for example, Japanese Unexamined Patent Publication JP-A 2001-193245).

Although blowing of rain water can be alleviated by the method, there poses a problem that humidity by rain water which has been brought therein once or dew condensation becomes further difficult to be exhausted or a metal is corroded by water stored at inside thereof.

### SUMMARY OF THE INVENTION

Hence, according to the invention, it is an object of the invention to provide a solar cell module capable of simply and conveniently carrying out operation of arranging a solar cell module and maintenance/check operation or the like on the roof and a solar cell array using the same. Further, it is an object thereof to provide an excellent solar cell module for a roof capable of providing a function of a snow guard to an arbitrary solar cell module and a solar cell array using the same.

Further, it is an object of the invention to provide a solar cell array facilitating to exhaust humidity and heat on a rear side of a tile, eliminating creak or wear of an overlapped portion of tiles and easily removing a solar cell module in maintenance or the like.

The invention provides a solar cell module for covering a roof board in cooperation with a tile by being arranged at a roof face along with the tile, the solar cell module comprising:

a positioning member positioned to the tile or another solar cell module in a state of being arranged at the roof board; and

a power generating member having a power generating function and attachably and detachably mounted to the positioning member.

According to the invention, the power generating member can be removed in a state of arranging the positioning member to the roof board. Thereby, operation of arranging the solar cell module or maintenance and check operation on the roof can be carried out simply and conveniently. For example, even when removal of the power generating member is required because of a failure in wiring the respective power generating members, destruction of the power generating member or the like after arranging the solar cell module, it is possible to easily remove the power generating member.

Further, in the invention, the positioning member includes a displacement blocking portion for blocking displacement to a lower side in a state of being arranged at the roof board.

According to the invention, the solar cell module can be prevented from being shifted to the lower side. For example, the displacement blocking portion is locked by a locking portion provided at the tile on the lower side, other solar cell module on the lower side or the roof board.

Further, in the invention, the positioning member is brought into contact with the roof board on both sides thereof in a vertical direction in a state of being arranged at the roof board.

In the invention, the positioning member supports each end portion of the power generating member in a state of being arranged at the roof board.

According to the invention, by supporting both end portions of the power generating member, deformation of the power generating member can be prevented. Thereby, destruction of the power generating member can be prevented even when the power generating member is loaded with snow.

Further, in the invention, the positioning member includes a guiding portion for guiding the power generating member to a predetermined mounting position.

According to the invention, the power generating member is mounted to the positioning member by being guided by the guiding member. Thereby, operation of mounting the power generating member can easily be carried out.

Further, in the invention, the solar cell module further comprises:

a connecting member for attachably and detachably fixing a power-generating-member-side fixing portion provided in the power generating member and a positioning-member-side fixing portion provided in the positioning member in a state of mounting the power generating member to the positioning member; and

a cover member covering the connecting member and attachably and detachably mounted to the power-generating-member-side fixing portion or the positioning-member-side fixing portion.

According to the invention, by fixing the positioning member and the power generating member by the connecting member, after mounting the power generating member, the power generating member can be prevented from being shifted from the positioning member. For example, the connecting member is realized by a bolt and either of the respective fixing portions is realized by being formed with a screw hole. Further, by covering the connecting member by the cover member, a beautiful appearance of the solar cell module can be promoted.

Further, in the invention, the cover member includes:

a main body portion;

a movable portion displaceably provided to the main body portion; and

resilient force generating means for exerting a resilient force directed to one side in a predetermined displacing direction to the movable portion,

wherein in a state in which the movable portion is disposed on the one side in the displacing direction, the movable portion is engaged with the positioning member or the power generating member and the cover member is mounted to the positioning member or the power generating member.

According to the invention, the movable member is maintained in a state where the resilient force is exerted thereto by the resilient force generating means and therefore, the cover member can be prevented from being detached from the positioning member or the power generating member. Further, by moving the movable portion on another side of the displacing direction against the resilient force, the state of engagement of the movable portion with the positioning member or the power generating member can be released. Thereby, the state of mounting the cover member and the positioning member or the power generating member can be released.

Further, in the invention, the power generating member having a power generating function has two end portions opposed to each other, an eaves side frame is provided at one end portion of the power generating member, and a ridge side frame is provided at another end portion of the power generating member, a cover member capable of being brought into contact with a ridge side frame of another solar cell module is attachably and detachably attached to the eaves side frame, the eaves side frame is provided with an eaves side frame engaging member which engages with the cover member, and the cover member is provided with a cover member engaging member which engages with the eaves side frame engaging member and an elastic member brought into contact with the eaves side frame engaging member to press.

According to the invention, the eaves side frame and the cover member can solidly be held by the elastic member and attachment and detachment of the cover member are facilitated. Thereby, operation of removing the solar cell module from a roof face is facilitated, and the solar cell module can easily be removed from the roof face for maintenance operation or checking operation of the solar cell module and operation of wiring the solar cell modules. Further, the solar cell module having high general purpose performance can be provided.

Further, product strength can also be changed by adding the product for reinforcement in site installing and therefore, the same member can deal therewith and a kind of the products can be reduced. For example, by adding the elastic member for reinforcement in site installing, it is possible to increase holding strength between the eaves side frame and the cover member, and the same member can deal therewith and a kind of product can be reduced.

Further, a screw or the like for fixing the cover member per se may not be provided and therefore, there is preferably achieved an advantage of improving an appearance thereof or eliminating a waterproof structure of the screw portion.

Further, in the invention, a snow guard portion is provided in the cover member.

According to the invention, it is facilitated to provide the snow guard portion at an arbitrary position of the solar cell module installed on the roof and therefore, the solar cell module which is a principal member can be constituted by one kind, it is not necessary to carry out installing construction by controlling a solar cell module for snow guard and a general solar cell module which is not provided with a snow guard separately and the construction can be simplified. Further, the change of specification after finishing construction is facilitated since only the cover member may be changed for snow guard. Further, a snow guard cover can be arranged in any of the solar cell modules and therefore, a consideration can be given such that a load of fallen snow does not concentrate on a specific solar cell module by arranging cover member having a snow guard mechanism not only for the solar cell module on the eaves side of the roof but also to the solar cell module at a middle position of the roof or on the ridge side.

Further, in the invention, in the solar cell module being installed to overlap a solar cell module at an upper stage and a solar cell module or a tile at a lower stage in such a manner that a ridge side end portion of the solar cell module or the tile at the lower stage is arranged below an eaves side end portion of the solar cell module or the tile at the upper stage, a clearance is provided between the solar cell module at the upper stage and the solar cell module at the lower stage or the tile in a vertical direction, an opening to the clearance is provided along an entire length of an eaves side face of the solar cell module at the upper stage and a ventilating path is constituted by the clearance in a direction orthogonal to the eaves side face.

According to the invention, humidity and heat on a rear side of a tile are facilitated to exhaust from the opening, further, since the ventilating path is constituted by the clearance in the direction orthogonal to the eaves side face, the humidity and the heat on the rear side of the tile are facilitated to exhaust also from a side opposed to the opening.

Further, in the invention, a lower face of the solar cell module at the upper stage is provided with an attaching metal piece for sandwiching a ridge side end portion of the solar cell module at the lower stage or a ridge side end portion of the tile, or an attaching metal piece engaging with a support metal piece fixed to a roof face.

According to the invention, a sliding contact portion with regard to the attaching metal piece can be excluded between the solar cell module at the upper stage and the solar cell module at the lower stage or the tile. Therefore, creak or wear at a tile overlapping portion with regard to the attaching metal piece can be eliminated.

Further, in the invention, a stopper for supporting the solar cell module at the upper stage when an eaves side end portion of the solar cell module at the upper stage is bent downwardly, is provided on a ridge side with respect to the eaves side face.

According to the invention, since the support stopper for supporting the solar cell module at the upper stage when the eaves side end portion of the solar cell module at the upper stage is bent downwardly is provided on the ridge side with respect to the eaves side face, when the eaves side end portion of the solar cell module at the upper stage is bent downwardly by an operator on the roof riding on the solar cell array or applying a load of fallen snow or the like, a frame member of the solar cell module is difficult to deform.

Further, in the invention, the stopper is a projection provided on the ridge side end portion of the solar cell module at the lower stage or the ridge side end portion of the tile along the entire length of the eaves side face.

According to the invention, since the support stopper is the projection provided on the ridge side end portion of the solar cell module at the lower stage or the ridge side end portion of the tile along the entire length of the eaves side face, rain water is made to be more difficult to flow therein.

Further, in the invention, the projection is inclined to an eaves side.

According to the invention, the support stopper is the projection provided on the ridge side end portion of the solar cell module at the lower stage or the ridge side end portion of the tile and inclined to the eaves side and inclined to the eaves side. Therefore, the projection serves as a rain baffle for preventing rain water from entering and rain water is made to be difficult to blow therein.

Further, in the invention, an attachable and detachable cover member is hung at the eaves end portion of the solar cell module at the upper stage.

According to the invention, since the attachable and detachable cover member is hung at the eaves end portion of the solar cell module at the upper stage, a beautiful appearance of the solar cell array can be promoted and the solar cell module can easily be removed in maintenance or the like.

Further, in the invention, in a state of being arranged to the roof board and positioned to the tile or other solar cell module, a clearance is formed in a vertical direction between the solar cell module and a tile or another solar cell module adjacent thereto in the vertical direction, and the clearance communicates with an outside space on an upper side of the roof.

According to the invention, humidity and heat between the solar cell module and the roof board is moved to the outside space by passing through the clearance. Thereby, humidity and heat can be prevented from staying at the clearance.

Further, in the invention, openings continuing from the clearance to outside space are respectively formed at a lower side end portion of the solar cell module and an upper side end portion of the solar cell module and the respective openings are formed over an entire length in an extending direction of the lower side end portion and the upper side end portion.

According to the invention, the opening can be made as large as possible and humidity and heat can further be prevented from staying at the clearance.

Further, in the invention, the clearance forms a ventilating path extending substantially linearly from the opening on the lower side to the opening on the upper side.

According to the invention, by moving heat and humidity to the outer space by passing the ventilating path, heat and humidity can further firmly be prevented from staying at the clearance.

Further, in the invention, a stopper for preventing deformation of the solar cell module on an upper side in a state of arranging the solar cell module on the roof board and bending the solar cell module on the upper side downwardly.

According to the invention, even when the solar cell module on the upper side is deformed, by supporting the solar cell module on the upper side by the stopper of the solar cell module on a lower side, the solar cell module can be prevented from being deformed significantly. Thereby, destruction of the solar cell module can be prevented even when an operator on the roof rides on the solar cell module and a load of fallen snow or the like is applied thereon. The stopper may be formed at either the solar cell module on the upper side and the solar cell module on the lower side.

Further, in the invention, the stopper faces an end face on an eaves side of the solar cell module on the upper side.

According to the invention, a portion which is deformed significantly can be supported and destruction of the solar cell module on the upper side can further firmly be prevented.

Further, in the invention, the stopper is formed over an entire length in the extending direction of the upper side end portion of the solar cell module.

According to the invention, the stopper serves as the rain baffle and rain water can be prevented from entering an interval between the roof board and the solar cell module. Further, when the solar cell module is brought into contact with the stopper, the load can be prevented from being concentrated on a specific portion of the solar cell module. Thereby, destruction of the solar cell module on the upper side can further firmly be prevented.

Further, in the invention, the stopper inclinedly extends to project on the upper side with the proximity to an eaves.

According to the invention, rain water can further firmly be prevented from entering the interval between the roof board and the solar cell module.

Further, the invention provides a solar cell array comprising a plurality of the above-described solar cell modules, the plurality of solar cell modules overlapping each other in such a manner that a ridge side end portion of an eaves side solar cell module is arranged below an eaves side end portion of a ridge side solar cell module and the respective solar cell modules being electrically connected to each other.

According to the invention, the solar generating member can be removed in a state of arranging the positioning member at the roof board as described above. Thereby, operation of arranging the solar cell array and the maintenance and check operation on the roof can be carried out simply and conveniently.

### BRIEF DESCRIPTION OF THE DRAWINGS

Other and further objects, features, and advantages of the invention will be more explicit from the following detailed description taken with reference to the drawings wherein:

FIG. 1 is a perspective view schematically explaining a solar cell module constituting a solar cell array according to the invention;

FIG. 2 is a sectional view schematically explaining a constitution of the solar cell module in FIG. 1;

FIG. 3 is an exploded perspective view of a solar cell module in FIG. 1;

FIG. 4 is a sectional view schematically explaining a constitution of a solar cell portion of the solar cell module and a casing in FIG. 2;

FIG. 5 is a perspective view schematically explaining an example of forming the solar cell array by arranging the solar cell modules in FIGS. 1 to 4 on a portion of a roof;

FIG. 6 is a sectional view explaining an example of a solar cell array according to the invention;

FIG. 7 is an enlarged sectional view of FIG. 6;

FIG. 8 is a sectional view showing a state where the solar cell module is positioned to tile;

FIG. 9 is a sectional view explaining another installing example of the solar cell array according to the invention;

FIG. 10 is a sectional view explaining still another installing example of the solar cell module;

FIG. 11 is an enlarged sectional view of FIG. 10;

FIG. 12 is a sectional view showing a state where the solar cell modules are positioned to each other;

FIGS. 13A to 13D are side views schematically explaining an example of attaching a frame cover of the solar cell module according to the invention;

FIG. 14 is a perspective view schematically explaining examples of the frame cover and a spring of the solar cell module according to the invention;

FIGS. 15A to 15D are sectional views schematically explaining an example of removing the frame cover of the solar cell module according to the invention;

FIGS. 16A and 16B are sectional views schematically explaining an example of a method of removing the solar cell module of the solar cell array according to the invention;

FIG. 17 is a perspective view schematically explaining drawing-out and containing of an output wiring of a solar cell from clearances between the solar cell modules as well as between the solar cell module and a tile according to the invention;

FIG. 18 is a sectional view schematically explaining a structure in which the frame cover of the solar cell module has a snow guard structure according to the invention;

FIG. 19 is a perspective view schematically explaining another example of forming the solar cell array by arranging the solar cell modules in FIGS. 1 to 4 on a portion of a roof;

FIG. 20 is a perspective view schematically explaining a solar cell module constituting a solar cell array according to the invention;

FIG. 21 is a sectional view schematically explaining a constitution of the solar cell module in FIG. 20;

FIG. 22 is an exploded perspective view of the solar cell module in FIG. 20;

FIG. 23 is a sectional view schematically explaining constitutions of a solar cell portion and a casing of the solar cell module in FIG. 20;

FIG. 24 is a perspective view schematically explaining an example of forming a solar cell array by arranging the solar cell module in FIGS. 20 to 23 on a portion of a roof;

FIG. 25 is a sectional view explaining an installing example of the solar cell module in FIGS. 20 to 23;

FIG. 26 is an enlarged sectional view of FIG. 25;

FIG. 27 is a sectional view showing a state where the solar cell module is positioned to tile;

FIG. 28 is a sectional view explaining another installing example of the solar cell module in FIGS. 20 to 23;

FIG. 29 is an enlarged sectional view of FIG. 28;

FIGS. 30A to 30C are sectional views explaining another installing example of the solar cell module in FIGS. 20 to 23;

FIGS. 31A to 31C are sectional views schematically explaining an example of a method of removing the solar cell module in FIGS. 20 to 23;

FIG. 32 is a perspective view schematically explaining an example of arranging the conventional solar cell tile on a portion of a roof;

FIG. 33 is a sectional view schematically explaining an example of arranging the conventional solar cell tile on a portion of the roof;

FIGS. 34A and 34B are sectional views schematically explaining a behavior of overlapping tiles in the conventional solar cell tile;

FIG. 35 is a perspective view schematically explaining an example of arranging the conventional solar cell tile on a portion of the roof; and

FIG. 36 is a sectional view schematically explaining an example of arranging the conventional solar cell tile on a portion of the roof.

### DETAILED DESCRIPTION

Now referring to the drawings, preferred embodiments of the invention are described below.

A detailed explanation will be given of an embodiment of a solar cell module 1 and a solar cell array 90 using the same according to the invention in reference to the schematically illustrated drawings as follows.

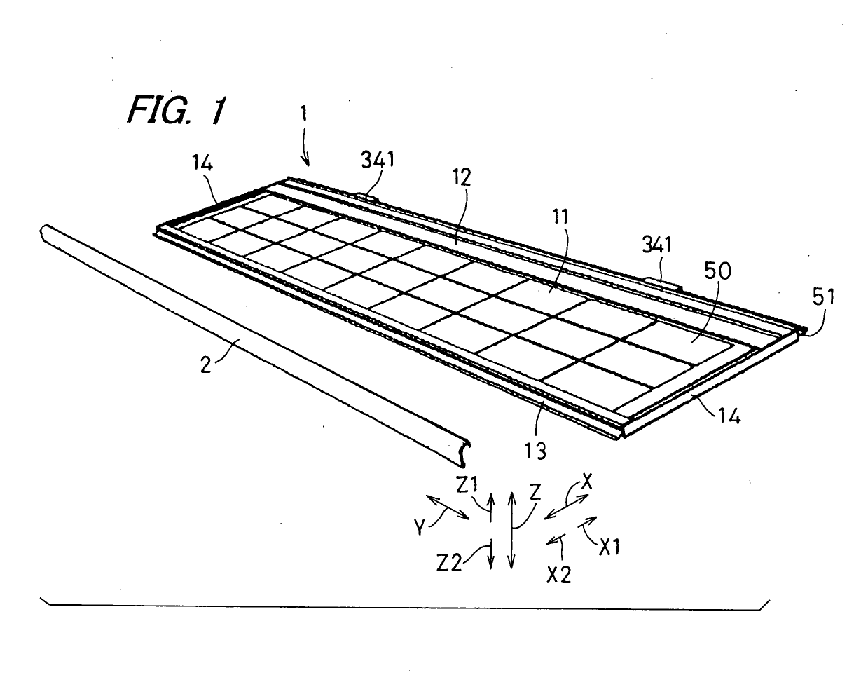

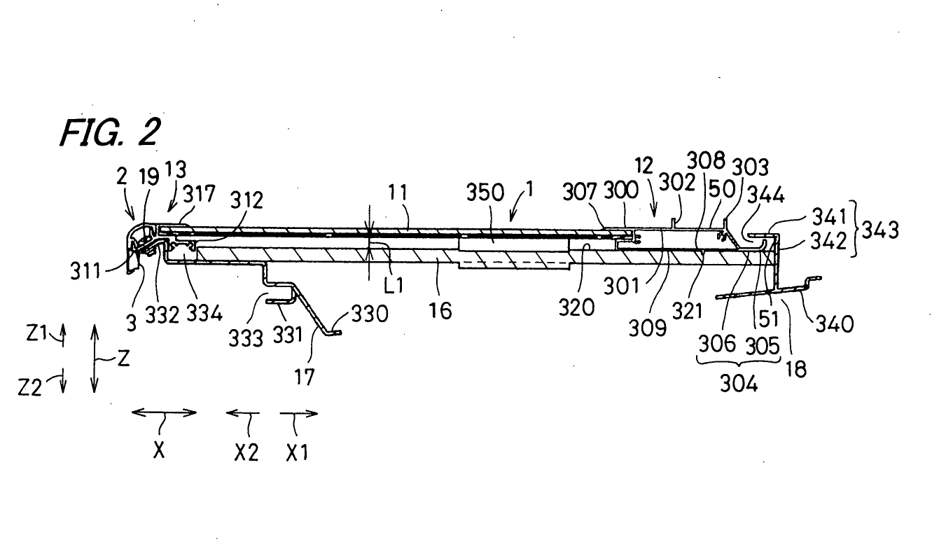

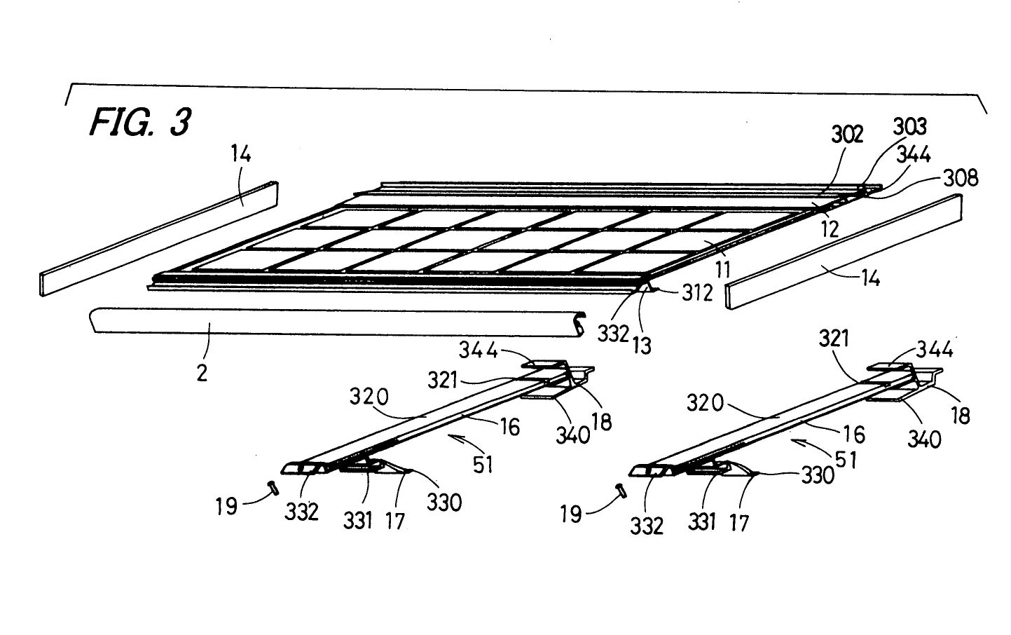

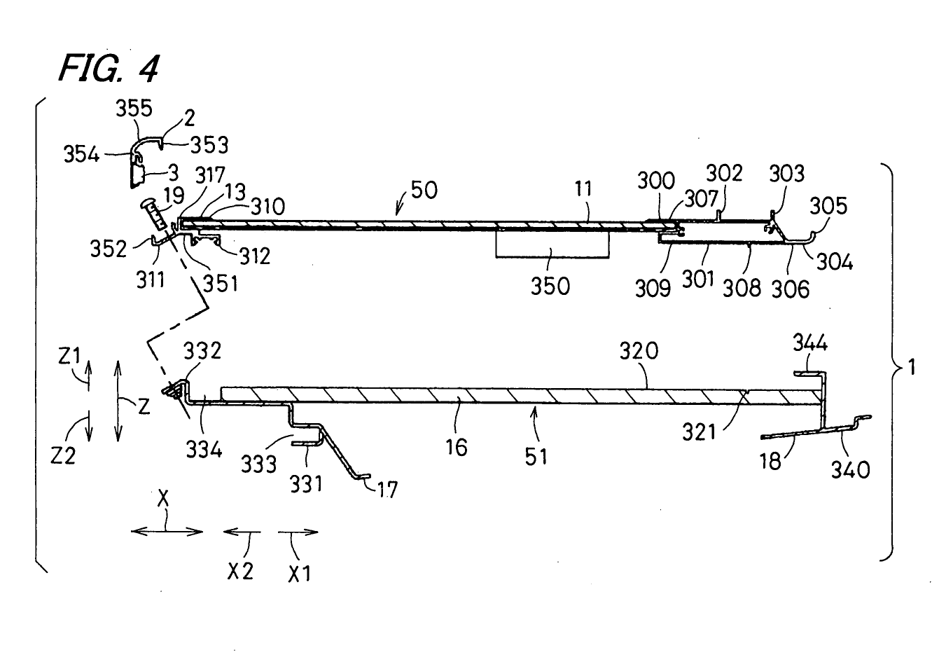

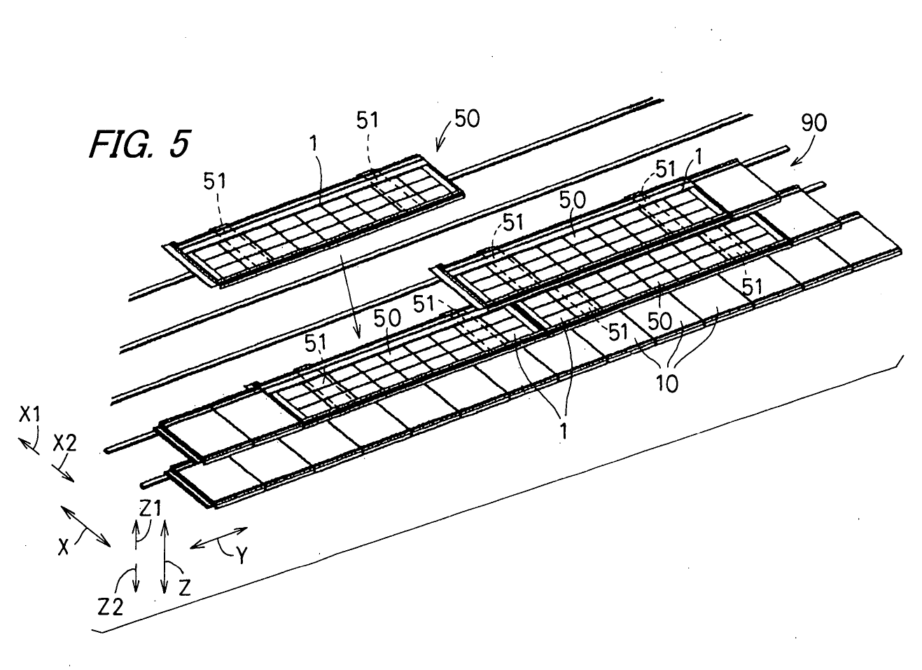

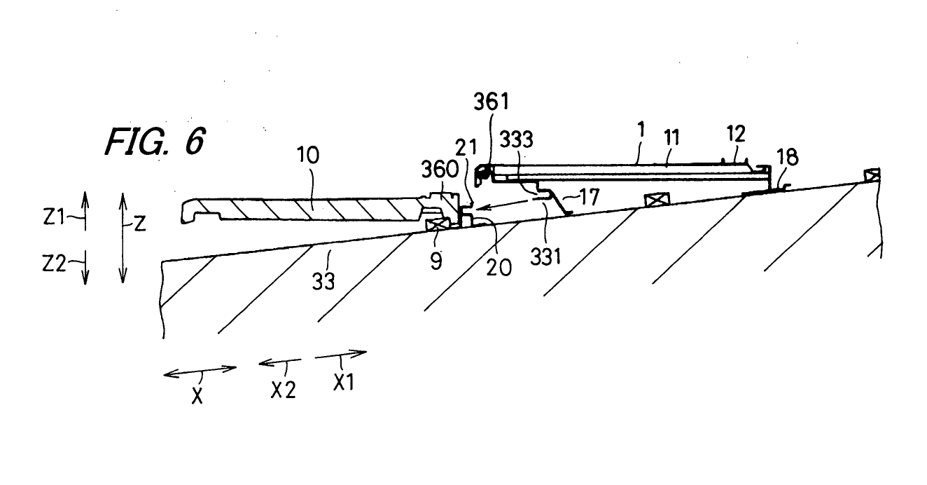

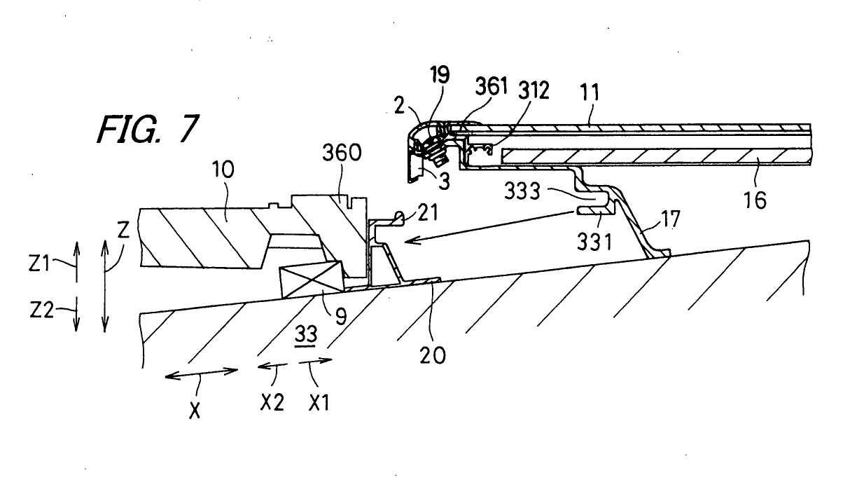

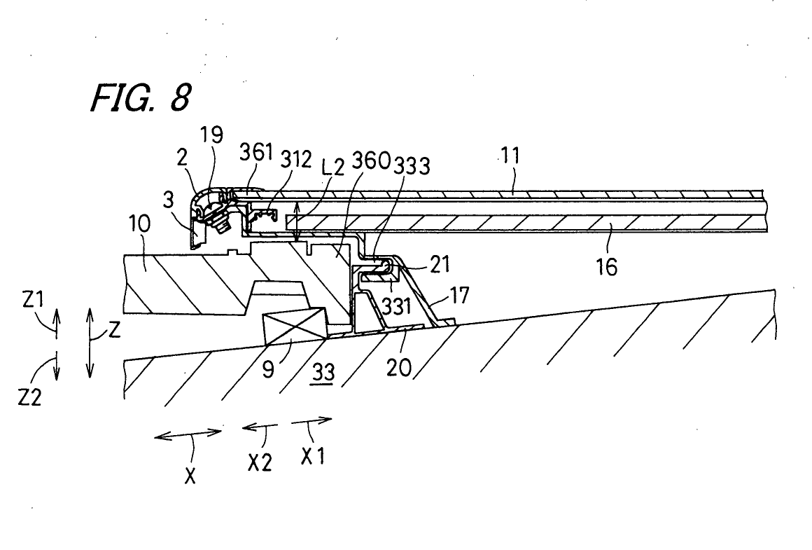

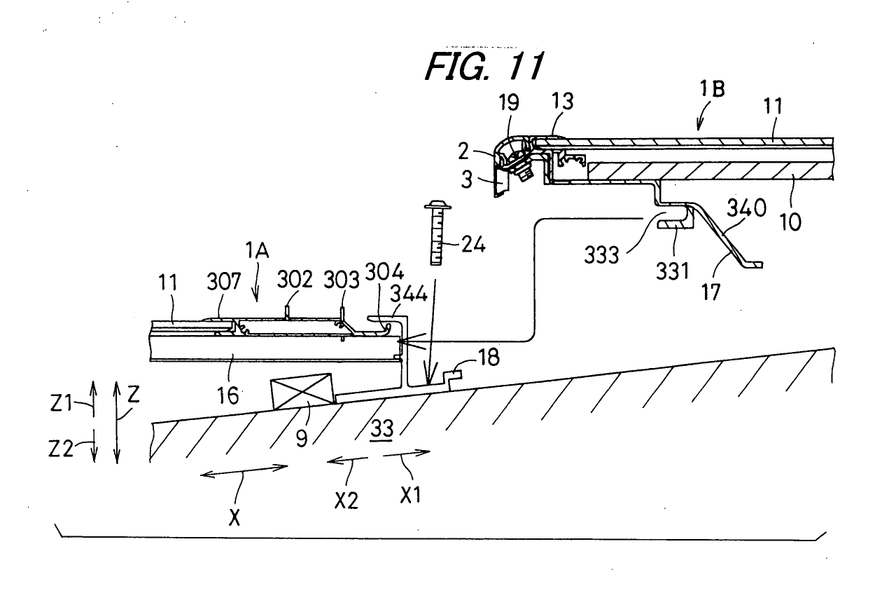

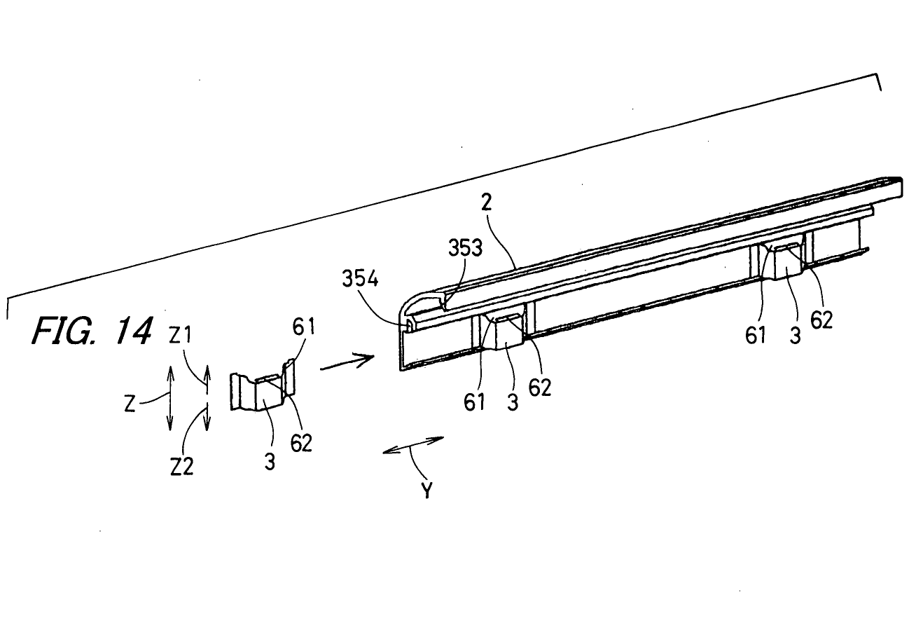

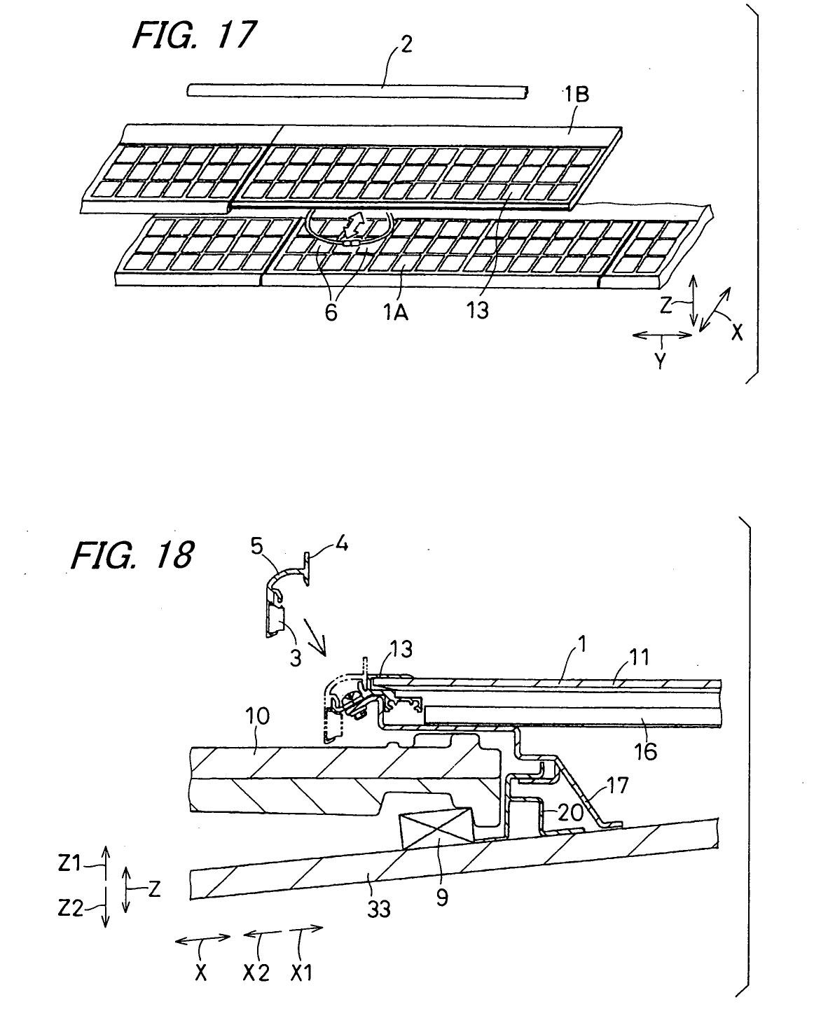

FIG. 1 shows a perspective view viewed from a light receiving face side of the solar cell module 1, FIG. 2 shows a sectional view of the solar cell module 1, FIG. 3 shows an exploded perspective view of the solar cell module 1, and FIG. 4 shows an exploded sectional view of the solar cell module 1 divided in two parts, respectively. Further, FIG. 5 shows a behavior of arranging the solar cell array 90 constituted by wiring and arranging a plurality of the solar cell modules 1 on a portion of a roof of a building. Further, FIGS. 6 to 13, FIGS. 15, 16, and 18 show partially sectional views of the solar cell module 1, FIG. 14 shows a perspective view of a frame cover 2 and FIG. 17 shows a behavior of taking out an output wiring of the solar cell module 1.

As shown in FIG. 1, the solar cell module 1 is constituted by including a solar cell portion 50 of a plate-like main body having a power generating function and constituting substantially a planar rectangular shape, a casing 51 and a frame cover 2. The solar cell portion 50 serves as a power generating member having power generating capability. Furthermore, the casing 51 serves as a positioning member that is positioned to the tile 10, another solar cell module or the roof board. The solar cell portion 50 is provided with a solar cell 11, a ridge side long side frame 12, an eaves side long side frame 13 and a side frame 14. The solar cell 11 is formed in a plate-like shape by adhering together a light transmitting board of glass, resin or the like and a plurality of cells of the solar cell. The ridge side long side frame 12 is arranged on a ridge side of the solar cell 11 and attached to the solar cell 11. The eaves side long side frame 13 is arranged on an eaves side of the solar cell 11 and attached to the solar cell 11. The side frames 14 are arranged on both left and right sides of the solar cell 11 and attached to the solar cell 11. The frame cover 2 is attached to the eaves side long side frame 13.

Further, in the invention, the eaves side is a lower side of the solar cell module 1 installed on a roof face. Further, the ridge side is an upper side of the roof face. Further, in the invention, in the case in which the solar cell module 1 is installed on the roof face, a direction in parallel with the roof and orthogonal to a horizontal line is defined as an inclined direction of X, a direction in parallel with the roof face and extending along the horizontal line is defined as a horizontal direction Y and a vertical direction is defined as a vertical direction Z. Further, one inclined direction X1 constitutes a direction directed to an upper side along the roof face and another inclined direction X2 constitutes a direction directed to the lower side along the roof face.

Further, as shown in FIGS. 2 to 4, the casing 51 is constituted by including a long support member 16, an eaves side fixing metal piece 17 and a ridge side fixing metal piece 18. The long support member 16 is provided on a rear face of a solar cell 11, i.e., on a side opposed to a light receiving face for receiving solar ray. The eaves side fixing metal piece 17 is attached to an eaves side of the long support member 16. The ridge side fixing metal piece 18 is attached to a ridge side of the long support member 16. Further, the solar cell portion 50 and the casing 51 are fastened by a fastening screw 19. The fastening screw 19 serves as a connecting member for fixing the solar cell portion 50 and the casing 51. Further, in an inner side of the frame cover 2, a spring 3 which is an elastic member engaged with the eaves side long side frame 13 is attached.

That is, as shown in FIG. 3, the solar cell module 1 includes the solar cell portion 50 and the casing 51. The solar cell portion 50 generates power by receiving solar ray on the light receiving face. One end portion of the casing 51 is attached to the roof. The solar cell portion 50 is attachably and detachably contained in the casing 51 attached to the roof and is coupled thereto by the fastening screw 19. Here, the fastening screw 19 is covered by the frame cover 2 for attaching the eaves side long side frame 13 to prevent from being seen from outside. Further, the frame cover 2 can easily be attached and detached by elastic deformation of the spring 3.

It is preferable that the solar cell 11 is constituted by including a light transmitting board made of glass, resin or the like provided on the light receiving face and a number of solar cell elements and attached to the light transmitting board by a sealing agent made of a resin or the like to accommodate the number of solar cell elements. Further, a material of single crystal or non-single crystal of, for example, silicon species semiconductor, a compound semiconductor of gallium arsenide or the like is used for the solar cell element and the elements are electrically connected to each other in series and/or in parallel. Further, although the frame provided on the solar cell main body is constituted by a metal material which is light-weighed and excellent in strength, such as aluminum or the like, the frame may be constituted by a resin material excellent in weather resistance. Further, it is preferable to use a metal material or the like excellent in strength for the casing 51.

Specifically, The solar cell 11 is formed in a shape of a rectangular plate. The ridge side long side frame 12 pinches a ridge side edge side 300 of the solar cell 11 and extends over an entire length in a width direction Y in which the ridge side edge side 300 extends. The ridge side long side frame 12 includes a pinching portion 307 for pinching the solar cell 11, a base portion 301 extending from the pinching portion 307 to a ridge side, stopper pieces 302, 303 projecting from the base portion 301 in an upper vertical direction Z1, and a engaging portion 304 extending from the base portion 301 toward the ridge side.

The stopper pieces 302, 303 are brought into contact with the solar cell module on the eaves side in the case in which the solar cell module on the ridge side is deformed downwardly when the solar cell module partially overlaps thereon in a vertical direction Z. Further, the stopper pieces 302, 303 prevent the solar cell module on the ridge side from being deformed further.

The base portion 301 is formed with a lower face 309 projecting downwardly from the rear face of the solar cell 11 and extending in parallel with the solar cell 11. With respect to the engaging portion 304, a front end portion 305 thereof is smoothly bent toward the upper direction Z1 relative to a remaining portion 306 thereof. When the solar cell module is arranged on the ridge side, the engaging portion 304 is fitted into a displacement blocking portion 331 formed in the solar cell module 1 on the ridge side to position the solar cell module 1 on the ridge side.

The eaves side long side frame 13 pinches an eaves side edge side 310 of the solar cell 11 and extends along an entire length in the width direction Y in which the eaves side edge side 310 extends. The eaves side long side frame 13 includes a pinching portion 317 for pinching the solar cell 11, a solar cell side fixing portion 311 extending from the pinching portion 317 to the eaves side and formed with an inserting through hole, and a fitting portion 312 extending from the pinching portion 317 toward the ridge side on a side of the rear face of the solar cell 11.

Two of the casings 51 are provided. As shown in FIG. 3, the respective casings 51 are provided at an interval therebetween in the width direction Y of the solar cell 11. The respective casings 51 are formed in the same shape. With respect to the casing 51, a dimension thereof in the width direction Y is shorter than that of the solar cell portion 50 and a dimension thereof in the inclined direction X is formed with a dimension substantially similar to that of the solar cell portion 50.

The long support member 16 is formed in a shape of a rectangular plate and a longitudinal direction thereof extends along the inclined direction X. An upper face 320 of the long support member 16 smoothly extends. In a state in which the solar cell portion 50 is mounted to the casing 51, the lower face 309 of the base portion 301 of the ridge side long side frame 12 is brought into contact with the upper face 320 of the long support member 16.

The eaves side fixing metal piece 17 includes a first leg portion 330 extending downward from the long support member 16 and brought into contact with the roof board, the displacement blocking portion 331 for blocking the casing 51 from deforming downwardly, and a casing side fixing portion 332 for being fixed to the solar cell side fixing portion 311. The displacement blocking portion 331 is formed with a engaging recess portion 333 in which a engaging portion 21 provided in the solar cell module on the eaves side, a tile on the eaves side or the roof board, fits.

The casing side fixing portion 332 is formed at a position opposed to the solar cell side fixing portion 311 in a state in which the solar cell portion 50 is mounted to the casing 51. The casing side fixing portion 332 is formed with a screw hole coaxial with the inserting through hole formed in the solar cell side fixing portion 311. The screw hole has a diameter smaller than that of the inserting through hole. The solar cell portion 50 and the casing 51 are attachably and detachably fixed by passing the fastening screw 19 as a connecting member through the inserting through hole of the solar cell fixing portion 311 and screwing the fastening screw 19 to the screw hole of the casing side fixing portion 332.

Further, the eaves side fixing metal piece 17 is formed with a fitting hole 334 having an opening on the upper side in cooperation with the long support member 16. Positioning of the solar cell portion 50 and the casing 51 in the inclined direction X can easily be carried out by fitting the fitting portion 312 of the eaves side long side frame 13 into the fitting hole 334 in a state in which the solar cell portion 50 is mounted to the casing 51.

The ridge side fixing metal piece 18 is formed with a second leg portion 340 extending downward from the long support member 16 and brought into contact with the roof board, and a guiding portion 343 extending upward from the long support member 16 and in which a front end portion 341 thereof is bent to the eaves side relative to a remaining portion 342 thereof. The second leg portion 340 is brought into contact with the roof board and is brought into contact with a cross piece provided on the roof board from the ridge side. Thereby, the casing 50 is positioned to the roof board and is prevented from displacing downwardly. The guiding portion 343 is formed with an engaging space 344 opened on the ridge side and gradually fitted with the engaging portion 304 of the solar cell portion 50. By providing the guiding portion 343, the solar cell portion 50 can easily be guided to a mounting position provided in the casing 51.

By bringing the respective leg portions 330, 340 of the eaves side fixing metal piece 17 and the ridge side fixing metal piece 18 into contact with the roof board, both ends of the long support member 16 can be supported and the solar cell portion 50 mounted to the casing 51 can stably be supported. Further, by supporting both sides in the width direction of the solar cell portion 50 by the two casings 51, the solar cell portion 50 can further stably be supported. Further, when the solar cell portion 50 is formed with a terminal box 350 to be connected with the output wiring 6, by arranging the two casings 51 at an interval therebetween, the terminal box 350 and casing 51 can be prevented from interfering with each other.

Further, as shown in FIG. 4, a projection 308 projecting from the lower face 309 of the base portion 301 of the ridge side long side frame 12 may be formed and a recess portion 321 may be formed in the upper face 320 of the long support member 16. The solar cell portion 50 and the casing 51 can be positioned to each other by fitting the projection 308 into the recess portion 321 in a state in which the solar cell portion 50 is mounted to the casing 51. Further, in the state in which the solar cell portion 50 is mounted to the casing 51, the solar cell 11 and the casing 50 are arranged at an interval L1 in the vertical direction Z. Thereby, even when accuracy of the casing 51 and the solar cell 50 is low, the solar cell portion 50 and the casing 51 can firmly be mounted to each other.

In the state in which the solar cell portion 50 is mounted to the casing 51, the frame cover 2 covers the eaves side long side frame 13. As shown in FIG. 4, the solar cell side fixing portion 311 of the eaves side long side frame 13 is formed with a first engaging recess portion 351 and a first engaging projection 352. The first engaging recess portion 351 and the first engaging projection 352 extends in the width direction Y. The frame cover 2 is formed with a second engaging projection 353 for engaging with the first engaging recess portion 351 and a second engaging recess portion 354 for engaging with the first engaging projection 352. By engaging the second engaging projection 353 of the frame cover 2 with the first engaging recess portion 351 and engaging the first engaging projection 352 of the solar cell side fixing portion 311 with the second engaging recess portion 354 of the frame cover 2, the frame cover 2 is prevented from displacing in the inclined direction X. Further, by mounting the frame cover 2 to the solar cell side fixing portion 311 in a state of fixing the solar cell side fixing portion 311 and the casing side fixing portion 332 by the fastening screw 19, the fastening screw 19 can be concealed.

The frame cover 2 includes a main body portion 355 formed with the second engaging projection 353 and the second engaging recess portion 354, mentioned above, a movable portion provided to the main body portion 355 displaceably in the inclined direction X, and resilient force generating means for exerting a resilient force directed to the upper inclined direction X1 to the movable portion. In the embodiment, the movable portion and the resilient force generating means are realized by a spring 3. In this case, a front end portion of the spring 3 serves as the movable portion. By engaging the front end portion of the spring 3 by the solar cell side fixing portion 311 or the casing side fixing portion 332, the frame cover 2 can be prevented from displacing in the vertical direction Z. Further, by moving the front end portion of the spring 3 in the lower inclined direction X2 by exerting a force against a spring force of the spring 3, a state of engaging the front end portion of the spring 3 and the solar cell side fixing portion 311 or the casing side fixing portion 332 can be released.

As shown in FIG. 5, the solar cell module 1 can be installed on the roof of the building mixedly with a tile 10 made of a ceramics or a metal. The solar cell module 1 can be installed to be surrounded by the tiles 10, installed to arrange the tile 10 between the solar cell modules 1, or installed on an entire face of the roof. Further, although a flat tile having a flat appearance is used for the tile 10 in the drawings, the tile 10 may be constituted by a wavy tile having a wavy surface, a construction method of alternately arranging tiles on the ridge side and on the eaves side may be adopted, or a method of arranging tiles aligned in a straight line from the ridge to the eaves may be adopted. Further, it is preferable to adjust a length of the solar cell module 1 to an outer shape dimension (or a width of a face emerged to a surface of one tile when tiles are overlapped) of the tile 10 substantially multiplied by an integer. Further, when the solar cell modules are aligned in the inclined direction X, it is preferable to shift positions in the width direction Y of the casing 51 of the solar cell module 1 on the eaves side and the casing 51 of the solar cell module 1 on the ridge side in the two solar cell modules 1 aligned in the inclined direction X. Thereby, the casings 51 of the respective solar cell modules 1 can be prevented from interfering each other.

Next, an explanation will be given of a method of installing the solar cell module 1 on the roof mixedly with the tile 10. As shown in FIGS. 6 to 8, the tile 10 is installed in the form of engaging a cross piece 9 arranged above a roof board 33 with a recess thereof such that the tile 10 is not shifted to drop to the eaves side. An eaves side receiving metal piece 20 is arranged on the roof board 33 on the ridge side of the tile 10 by fixing the eaves side receiving piece 20 by a screw or a nail, and the solar cell module 1 is moved to contain the metal piece engaging portion 21 of the eaves side receiving metal piece 20 in the engaging recess portion 333 formed on the displacement blocking portion 331 of the eaves side fixing metal 17 of the solar cell module 1. Thereby, the solar cell module 1 can be fixed onto the roof and the tile 10 and the solar cell module 1 can be overlapped in such a manner that a ridge side end portion of the solar cell module or tile on the eaves side is arranged below an eaves side end portion of the solar cell module or tile on the ridge side. The solar cell module 1 is prevented from moving to the eaves side and the eaves side end portion 361 of the solar cell module 1 is arranged above the ridge side end portion 360 of tile 10. In this time, the casing 51 supports the solar cell portion 50 at an interval L2 in the vertical direction Z relative to the tile 10. Further, the ridge side fixing metal piece 18 of the solar cell module 1 is fixed by striking a nail 24, a screw nail or the like onto the roof board.

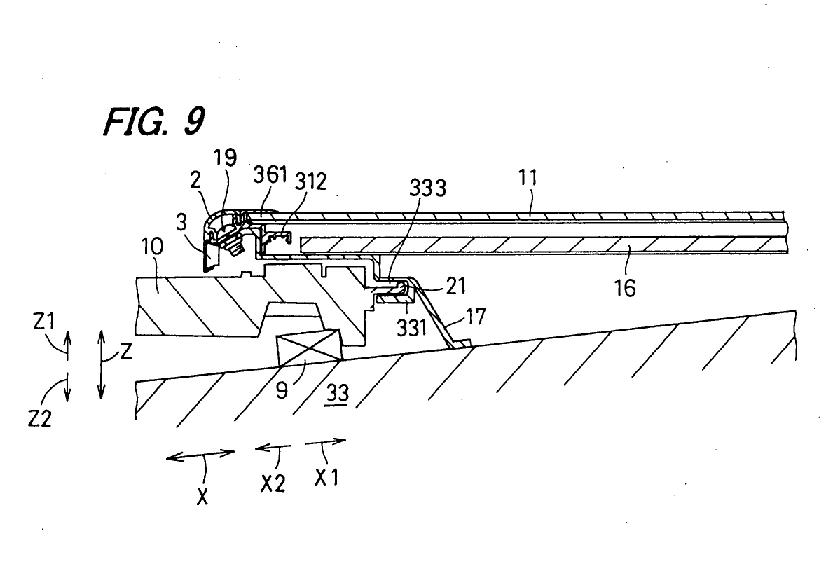

As shown in FIG. 9, the engaging portion 21 may be formed on the ridge side portion 361 of the tile 10. Also in the case, in a similar fashion mentioned above, the solar cell module 1 is moved to contain the engaging portion 21 in the engaging recess portion 333 formed on the displacement blocking portion 331 of the eaves side fixing metal 17 of the solar cell module 1 so as to fix the solar cell module 1 to the roof board.

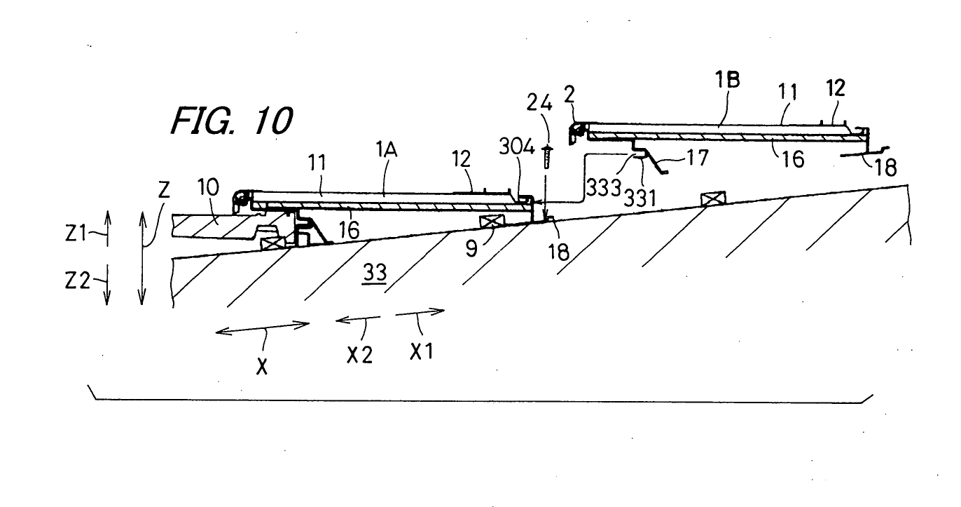

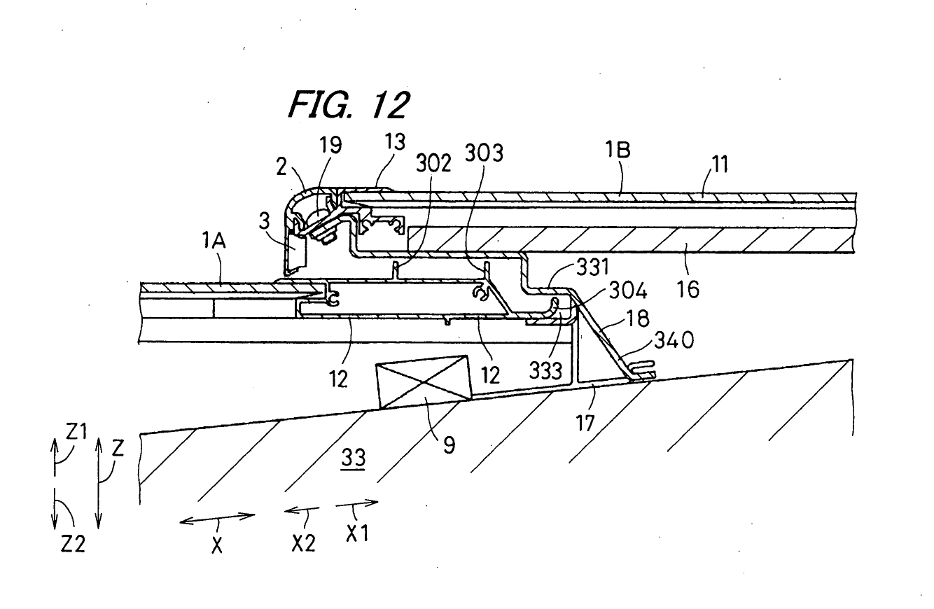

Also in the case of overlapping the solar cell modules 1 in such a manner that a ridge side end portion of a solar cell module on the eaves side is arranged below an eaves side end portion of a solar cell module on the ridge side, similarly, as shown in FIGS. 10 to 12, the solar cell module 1B of the ridge side is moved to contain the engaging portion 304 of the ridge side long side frame 12 of the solar cell module 1A on the eaves side in the engaging recess portion 333 formed on the displacement blocking portion 331 of the eaves side fixing metal piece 17 of a solar cell module 1B on the ridge side, thereby the solar cell modules can be overlapped in tiles as shown in FIG. 12.

The ridge side long side frame 13 of the solar cell module 1B on the ridge side fixed in this way is arranged to cover an upper portion of the ridge side long side frame 12 of the solar cell module 1A on the ridge side, a rain baffle structure is formed by the frame cover 2 attached to the eaves side long side frame 13 of the ridge side solar cell module 1B and the stopper pieces 302 and 303 of the eaves side solar cell module 1A to thereby prevent rain or wind from entering as less as possible. That is, the frame cover 2 extends along the entire length in the width direction Y of the eaves side long side frame in the width direction Y, and extends to the position close to the eaves side long side frame 12 of the ridge side solar cell module 1A in the vertical direction Z. In the same way, the stopper pieces 302 and 303 extend along the entire length in the width direction Y of the ridge side long side frame 12 in the width direction Y, and extend to the position close to the eaves side long side frame 13 of the ridge side solar cell module 1B in the vertical direction Z.

Further, by making a space between the frame cover 2 and a screw upper portion of the fastening screw 19 shorter than an entire length of the screw, a screw head can be pressed such that the fastening screw 19 is not completely detached when the fastening screw 19 is loosened.

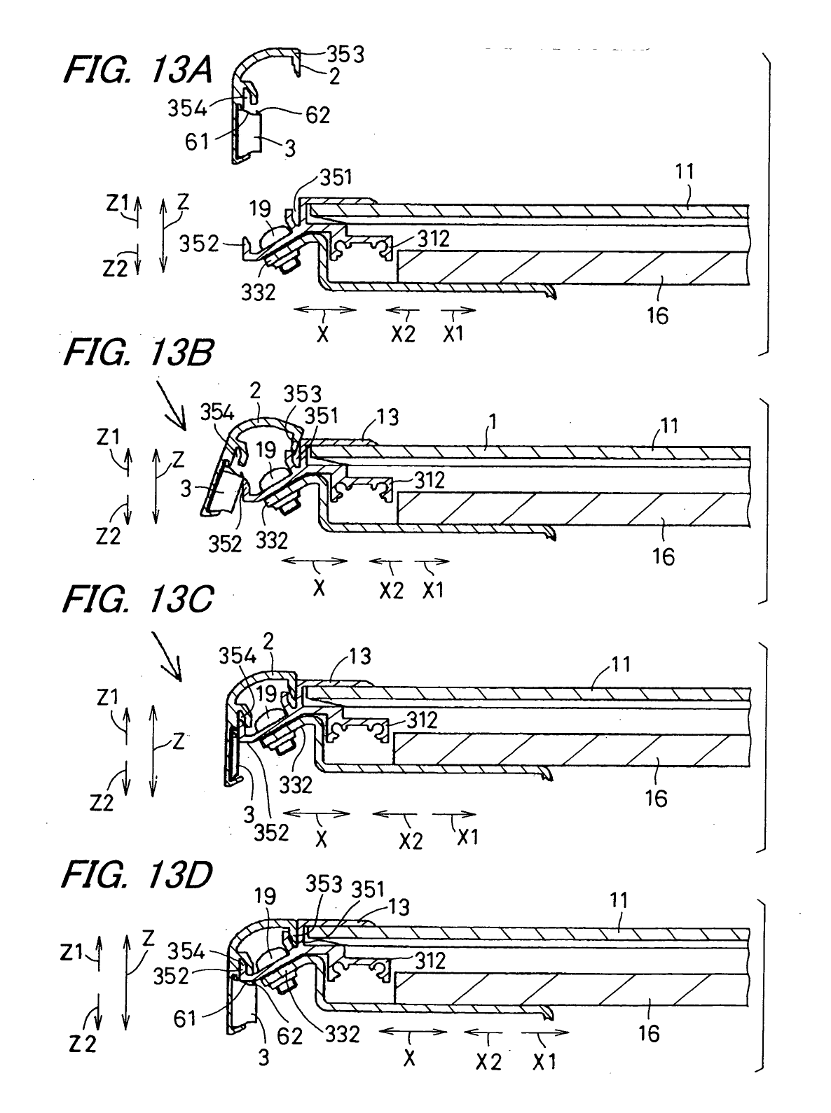

FIGS. 13A to 13D show a method of attaching the frame cover 2. As shown in FIG. 13A, the spring 3 having an inclined portion 61 is attached on an inner side of the frame cover 2. An upper face of the inclined portion 61 inclines to the lower direction Z2 with the advancement to one inclined direction X1. Further, as shown in FIG. 13B, the second engaging projection 353 which is an engaging member of the frame cover 2 is lightly inserted into the first engaging recess portion 351 which is an engaging member of the eaves side long side frame 13 of the solar cell module 1 and is pushed in a slanted lower direction. Thereby, as shown in FIG. 13C, the spring 3 is compressed by elastic deformation, the second engaging recess portion 354 which is an engaging member of the frame cover 2 is moved onto the first engaging projection 352 which is an engaging member of the eaves side long side frame 13, and the second engaging projection 353 and the first engaging recess portion 351 and the second engaging recess portion 354 and the first engaging projection 352 are fitted into each other as shown in FIG. 13D. At this occasion, the inclined portion 61 of the spring 3 is moved to a position opposed to the lower face of the eaves side long side frame 13 by recovery force of the spring 3. Thereby, the displacement toward the upper direction Z1 of the frame cover 2 is blocked relative to the eaves side long side frame 13, and the frame cover 2 and the eaves side long side frame 13 are solidly held.

A contact point of the inclined portion 61 with the eaves side long side frame 13 can be moved in a vertical direction in accordance with an inclined degree thereof, and a dimensional error or accuracy of the long side frame 13, the frame cover 2, or the spring 3 per se can be absorbed. Further, the spring 3 also serves to alleviate accuracy of fitting the eaves side long side frame 13 and the frame cover 2. Further, by providing a spring projected portion 62 which inclines in the upper direction Z1 with the advancement to another inclined direction X2, on a tip of the inclined portion 61, the spring projected portion 62 gets a claw into the eaves side long side frame 13 and the frame cover 2 can further solidly be held by making the spring 3 difficult to contract. Further, according to the above-described construction method, a screw or the like for fixing the frame cover 2 may not be provided in the surface. Therefore, there is preferably achieved an advantage of improving the appearance and eliminating a waterproof structure of the screw portion, it is not necessary to separately prepare a fixing member of a screw or the like. Therefore, the attaching operation is simple and convenient.

Although the spring 3 may be attached to the frame cover 2 by an adhesive, a screw, a rivet or the like, the spring 3 may be inserted into a slit formed on the frame cover 2 as shown in FIG. 14. The spring 3 inserted into the slit is formed so as to be movable in the width direction Y. Further, a number of pieces of the springs 3 for attaching to the frame cover 2 may be selected in accordance with a length of the frame cover 2 or elastic strength of the spring 3, in site installation, product strength can also be changed by adding the spring 3 for reinforcement and therefore, the same member can deal therewith and a kind of the product can be reduced.

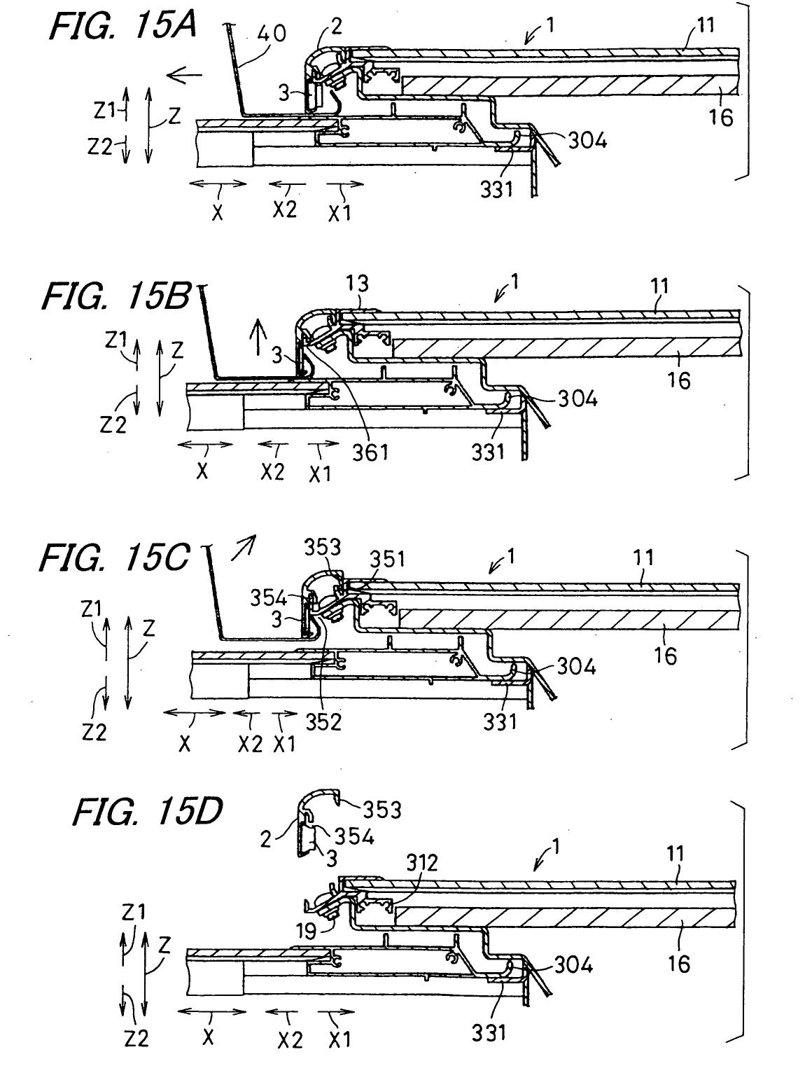

Next, FIGS. 15A to 15D show a method of removing the frame cover 2. As shown in FIG. 15A, a removing standard tool 40 is inserted from below the frame cover 2 into the inner side of the frame cover 2 and thereafter pulled in a direction of an arrow in the drawing to compress the spring 3. When the spring 3 is compressed, as shown in FIG. 15B, the engagement of the solar cell module 1 with the eaves side long side frame 13 is released, so that the spring 3 can pass through a clearance between the frame cover 2 and the first engaging projection 352 of the eaves side long side frame 13. That is, this results in a state of removing the frame cover 2 from the eaves side long side frame 13.

Therefore, the frame cover 2 is lifted upwardly as an arrow shown in FIG. 15B, and as shown in FIG. 15C, the fitting of the second engaging projection 353 into the first engaging recess portion 351 and the fitting of the second engaging recess portion 354 into the first engaging projection 352 are released, and as shown in FIG. 15D, the frame cover 2 can easily be removed.

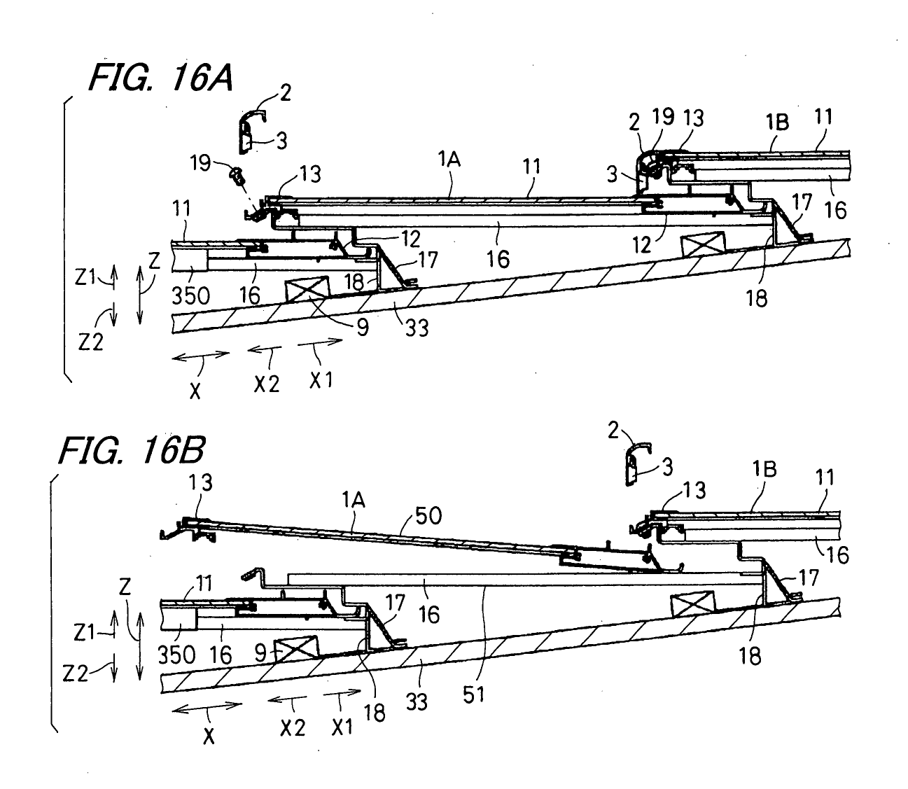

By enabling to easily remove the frame cover 2 in this way, as shown in FIG. 16A, by removing the frame cover 2 of the eaves side solar cell module 1A after the installation is finished once and the eaves side solar cell module 1A is engaged with the ridge side solar cell module 1B, the fastening screw 19 for coupling the solar cell portion 50 and the casing 51 can easily be removed, and as shown in FIG. 16B, the solar cell portion 50 of the eaves side solar cell module 1A can be removed by removing also the frame cover 2 of the ridge side solar cell module 1B. Further, also the solar cell modules 1A and 1B can easily be fitted together by a reverse procedure thereto. Further, by utilizing the procedure, as shown in, for example, FIG. 17, when the frame cover 2 is removed, there is produced a clearance communicating with the rear face of the eaves side solar cell module 1A between the ridge side solar cell module 1B and the eaves side long side frame 13 of the eaves side solar cell module 1A and therefore, the output wiring 6 of the eaves side solar cell module 1A can be drawn therefrom. Hence, in installing the solar cell module 1, the frame cover 2 is removed, after finishing of arrangement of the solar cell module in a state where the output wiring 6 of the solar cell module 1 is drawn to outside, wiring is carried out, the output wiring 6 is pushed from the clearance to the rear face of the solar cell module and thereafter, the frame cover 2 is attached.

Thereby, arrangement of the solar cell module 1 and wiring of the output wiring can be operated separately and therefore, a complicated construction method of interposing a wiring step in arranging the solar cell module 1 can be simplified to constitute a smooth arranging operation. Further, the wiring can be contained after confirming a situation of connecting the output wiring and therefore, a failure in wiring is difficult to be brought about. Further, a confirmation or correction of a wiring state in the case of causing a problem in wiring can easily be carried out only by removing the frame cover 2.

Further, by utilizing the fact that the frame cover 2 of the solar cell module 1 can be removed, as shown in FIG. 18, a snow guard cover 5 having a snow guard mechanism (snow guard portion) can attachably and detachably be attached to the eaves side frame. By using the snow guard cover 5 having a snow guard projected portion 4 (snow guard portion) projected upwardly from the light receiving face as a frame cover, the snow guard mechanism can easily be constituted at an arbitrary position on the roof and therefore, it is not necessary to fabricate the special solar cell module 1 dealing with snow guard, it is not necessary to carry out installing construction by controlling a solar cell module for snow guard and a general solar cell module 1 which is not provided with a snow guard separately and the construction can be simplified.

Since the frame cover 2 may only be changed for snow guard, the specification can easily be changed after finishing construction. Further, the snow guard cover 5 can be arranged at an arbitrary position of the solar cell module 1 and therefore, a consideration can also be given such that load of fallen snow does not concentrate on a specific solar cell modules 1 by arranging the snow guard cover 5 not only on the eaves side of the roof but also a middle portion thereof or the ridge side. Therefore, strength required for the solar cell module per se can also be alleviated.

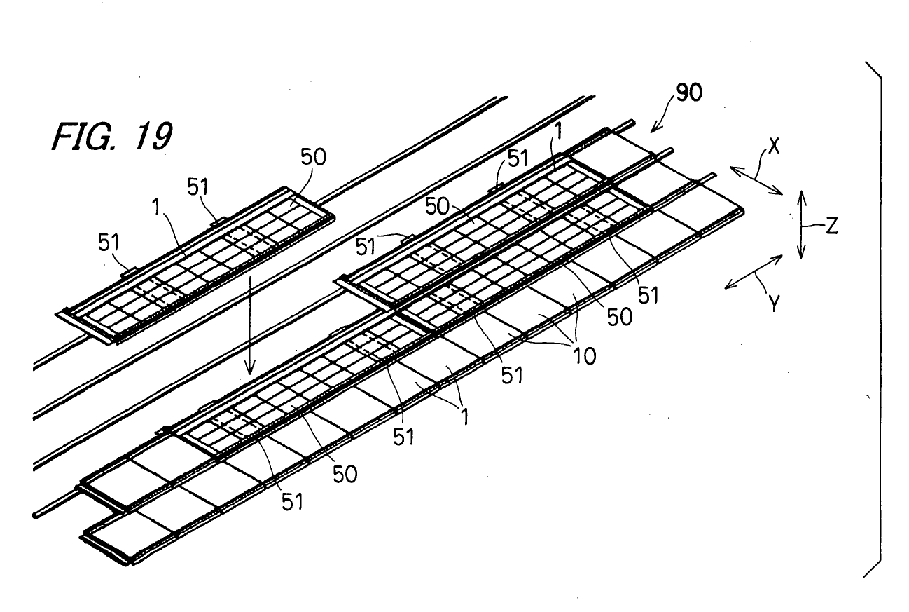

Further, as shown in FIG. 19, in a case of aligning the solar cell modules 1 in the inclined direction X, by shifting a position of the casing 51 of the solar cell module on the upper side and a position of the casing 51 of the solar cell module on the lower side in the width direction Y, it is possible to prevent the casings from interfering with each other and form the solar cell array 90.

As has been explained in details, according to the solar cell array 90 overlapping the solar cell modules 1 in such a manner that a ridge side end portion of a solar cell module on the eaves side is arranged below an eaves side end portion of a solar cell module on the ridge side, even in a state in which a portion of the solar cell module 1 is covered by other solar cell module or the tile, the solar cell module 1 can easily be removed, replacement or maintenance/check operation or the like of the solar cell can simply be carried-out and the confirmation of wiring between the solar cell modules can easily be carried out. Further, even when there is a failure in wiring or the like, or construction is carried out again for correction, the correction or the like can be carried out in an extremely short period of time.

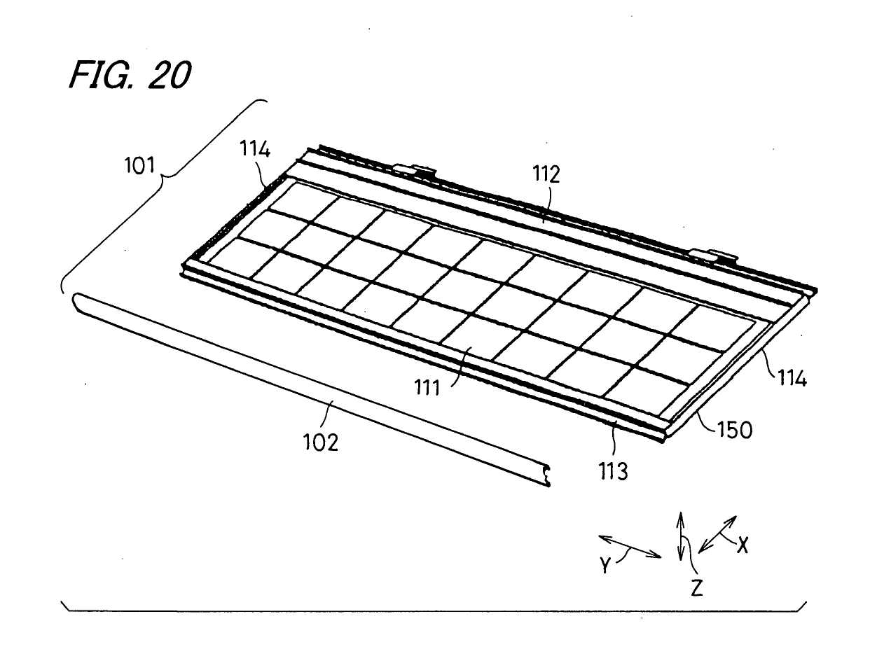

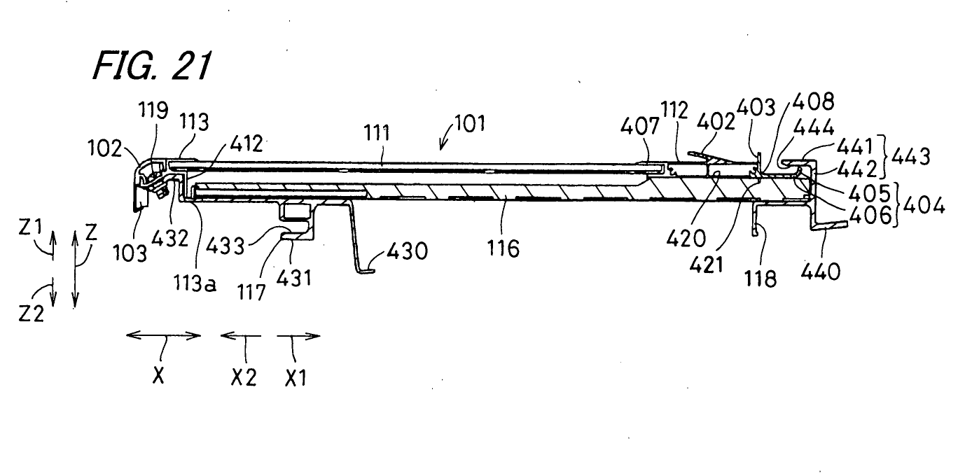

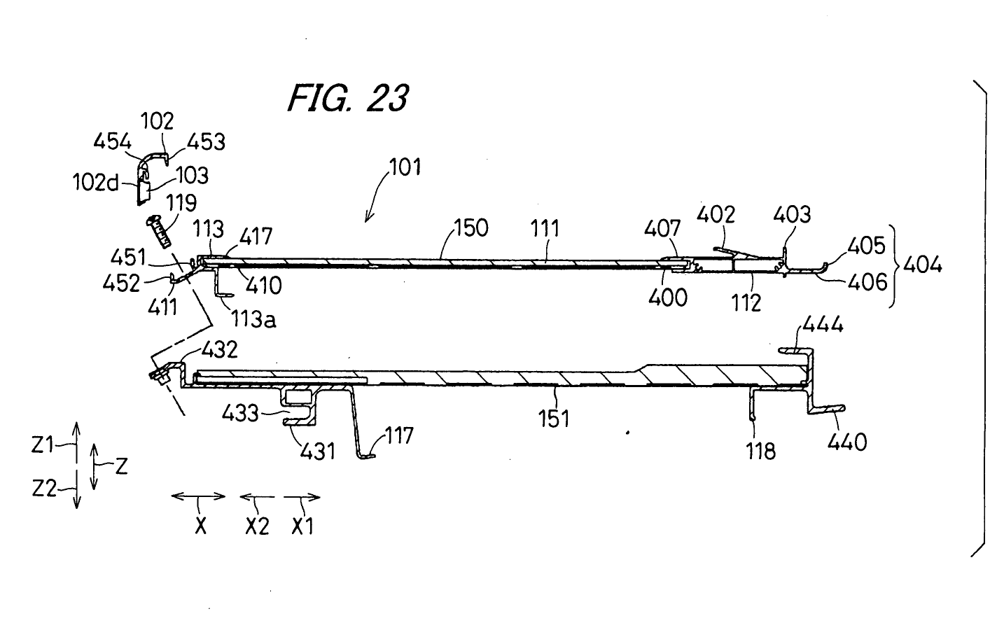

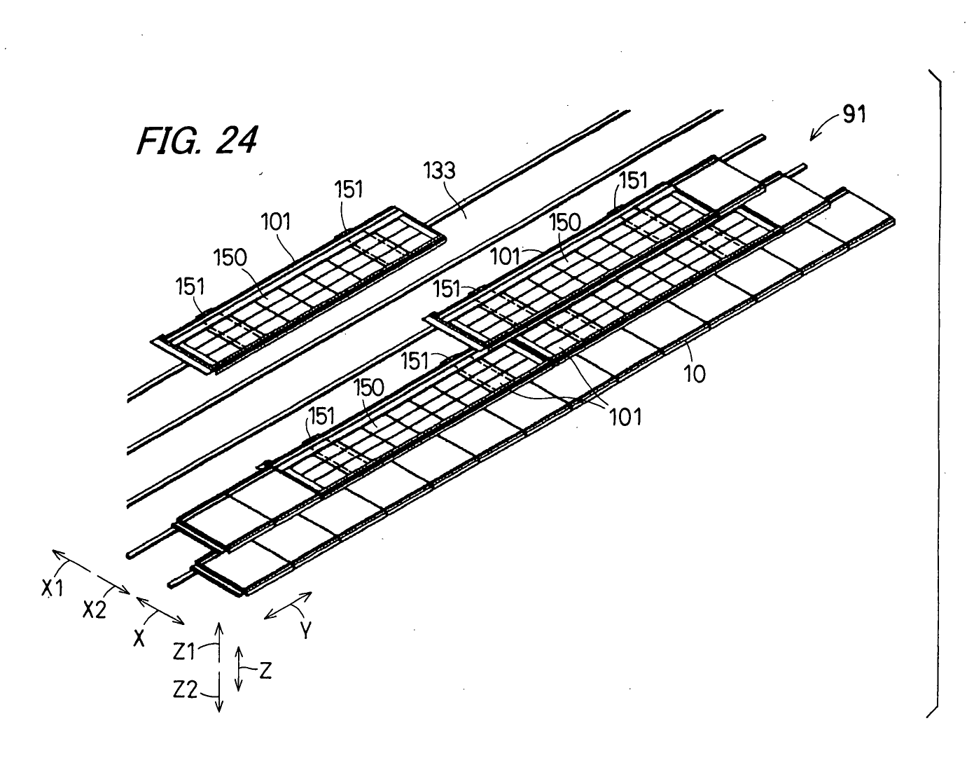

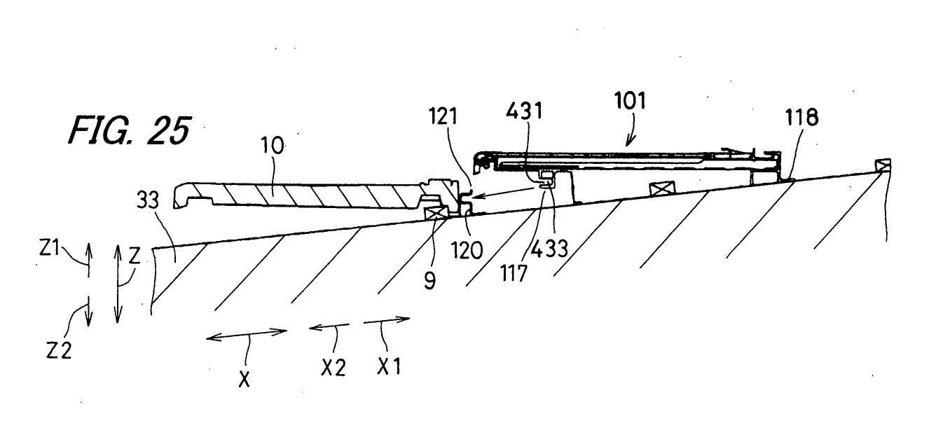

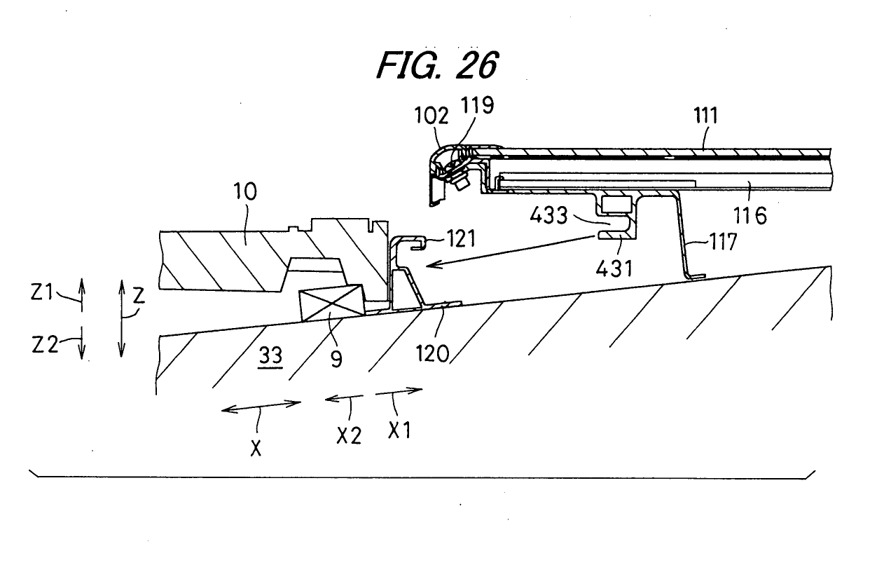

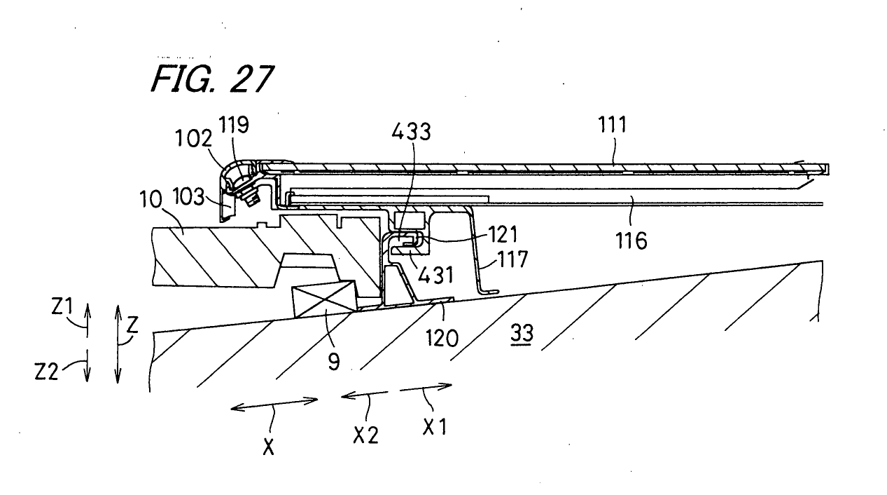

A detailed explanation will be given of an embodiment of a solar cell module 101 and a solar cell array 91 using the same according to the invention in reference to the schematically illustrated drawings as follows. FIG. 20 shows a perspective view viewed from a side of a light receiving face of the solar cell module 101, FIG. 21 shows a sectional view of the solar cell module 101, FIG. 20 shows an exploded perspective view of the solar cell module 101, and FIG. 23 shows an exploded sectional view of the solar cell module 101 divided in two parts. Further, FIG. 24 shows a behavior of arranging a solar cell array 91 constituted by wiring to arrange a plurality of the solar cell modules 101 on a portion of a roof 98 of a building. Further, FIGS. 25 to 31 show partially sectional views of the solar cell module 101.

As shown in FIG. 20, the solar cell module 101 is constituted by including a solar cell portion 150 of a plate-like main body having a power generating function and formed in a substantially planar rectangular shape, a casing 151 and a frame cover 102. The solar cell portion 150 is provided with a solar cell 111, a ridge side long side frame 112, an eaves side long side frame 113 and a side frame 114. The solar cell 111 is formed by attaching together a plurality of solar cell elements to a light transmitting board of glass, resin or the like. The ridge side long side frame 112 is arranged on the ridge side of the solar cell 111 and is attached to the solar cell 111. The eaves side long side frame 113 is arranged on the eaves side and is attached to the solar cell 111. The side frames 114 are arranged on both left and right sides of the solar cell 111 and are attached to the solar cell 111. The frame cover 102 is attached to the eaves side long side frame 113 arranged on the eaves side and brought into contact with the eaves side frame of other solar cell module 101. The casing 151 supports the solar cell portion 150 and fixes the solar cell portion 150 to the roof or the like. As shown in FIG. 21, the solar cell portion 150 and the casing 151 are fastened to a fixing rail 116 provided on a rear face of the solar cell portion 150 by a casing constituted by attaching an eaves side fixing metal piece 117 and a ridge side fixing metal piece 118 and a fastening screw 119. That is, as shown in FIG. 24, with respect to the solar cell module 101, the solar cell portion 150 for generating power is attachably and detachably contained in the casing 151 whose one end portion is attached to the roof and is coupled thereto by the coupling screw 119. The coupling screw 119 is covered by the frame cover 102 to which the eaves side long side frame 113 is attached and a clearance therebetween is made to be difficult to be seen from outside. In the embodiment, since the frame cover 102 is mounted, a front face of the frame cover 102 forms an eaves side face 102d. Further, a spring 103 supported by the eaves side long side frame 113 is attached to an inner side of the frame cover 102 and the frame cover 102 can easily be attached and detached to facilitate to access to the fastening screw 119.

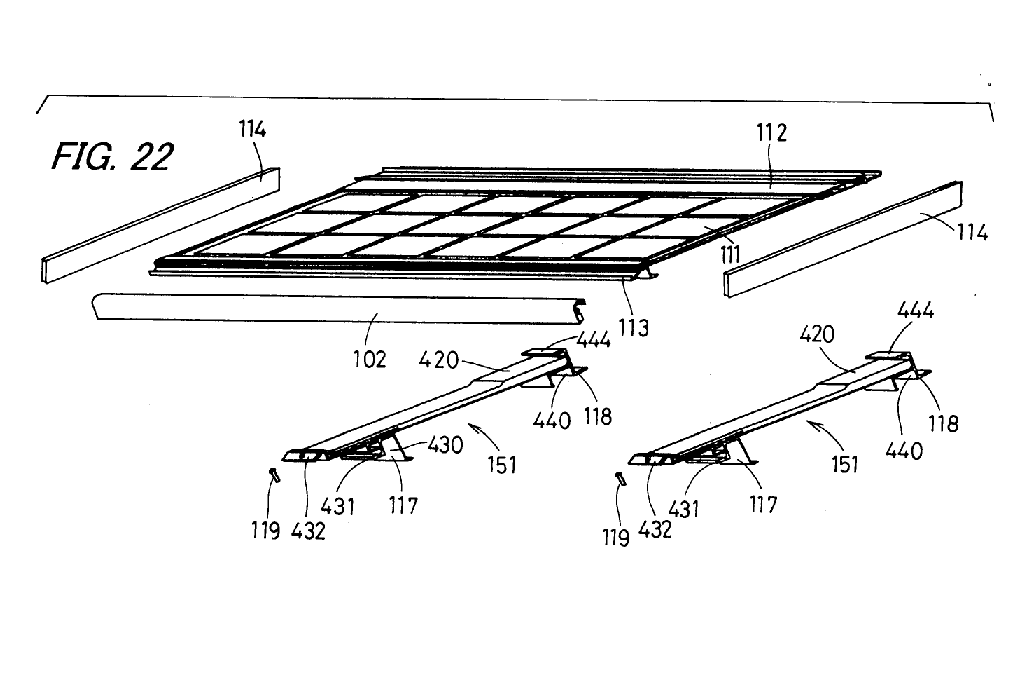

The solar cell module 101 shown in FIGS. 20 to 23 has substantially similar constitution to the solar cell module 1 shown in FIGS. 1 to 4. Therefore, values adding 100 to the reference numerals of the solar cell module 1 shown in FIGS. 1 to 4 are used as the reference numerals of the solar cell module 101 in FIGS. 23 to 23. Furthermore, with respect to the same constitution, explanations thereof may be omitted.

Meanwhile, a lower portion of the eaves side long side frame 113 of the solar cell portion 150 is provided with a frame lower portion supporting portion 113a for supporting a load from a surface side of the solar cell module 101, and the ridge side long side frame 112 is provided with a frame upper portion stopper projections 402 and 403 for receiving the frame lower portion supporting portion 113a. Further, the frame lower portion supporting portion 113a is received by both or either of a first frame upper portion stopper projection 402 and a second frame upper portion stopper projection 403.

In the following, a construction method of installing the solar cell array 91 on the roof of the housing with the solar cell module 101 mixed with the tile 10 is similar to the above-described construction method. That is, the solar cell module 101 can be installed on a roof 133 of a building mixedly with the tile 10 made of a ceramics or a metal and can be installed to be surrounded by the tiles 10, installed by arranging the tile 10 between the solar cell modules 101, or a total face of the roof can be constituted by the solar cell modules 101. Further, although a flat plate tile having a flat appearance is used for the tile 10, the tile 10 may be constituted by a wavy tile and even in a construction method of alternately arranging the tiles on the ridge side and on the eaves side, the tiles may be arranged to align on a straight line from the ridge to the eaves. Further, it is preferable to adjust a length of the solar cell module M to an outer dimension (or, a width of a face thereof emerging a surface of one tile when the solar cell modules M are overlapped in such a manner that a ridge side end portion of an eaves side solar cell module is arranged below an eaves side end portion of a ridge side solar cell module) of the tile 10 substantially multiplied by an integer.

As shown in FIGS. 25 to 27, the tile 10 is installed in the form of engaging a cross piece 29 arranged above the roof board 31 with a recess thereof such that the tile 10 is not shifted to drop to the eaves side. A support metal piece 120 is arranged on the roof board 33 on the ridge side of the tile 10 by fixing the support metal piece 20 by a screw or a nail, and a metal piece engaging portion 121 of the support metal piece 120 is contained in an engaging recess portion 433 formed by a displacement blocking portion 431 of the eaves side fixing metal piece 117 of the solar cell module 101. Thus, the solar cell module 101 can be fixed onto the roof. As a result, the tile 10 and the solar cell module 101 can be can be overlapped in such a manner that a ridge side end portion of a solar cell module or a tile on the eaves side is arranged below an eaves side end portion of a solar cell module or a tile on the ridge side. Further, a ridge side fixing metal piece 118 of the solar cell module 101 is fixed by striking a nail or a screw onto the roof board 33. Thereby, the solar cell module 101 is fixed onto the roof.

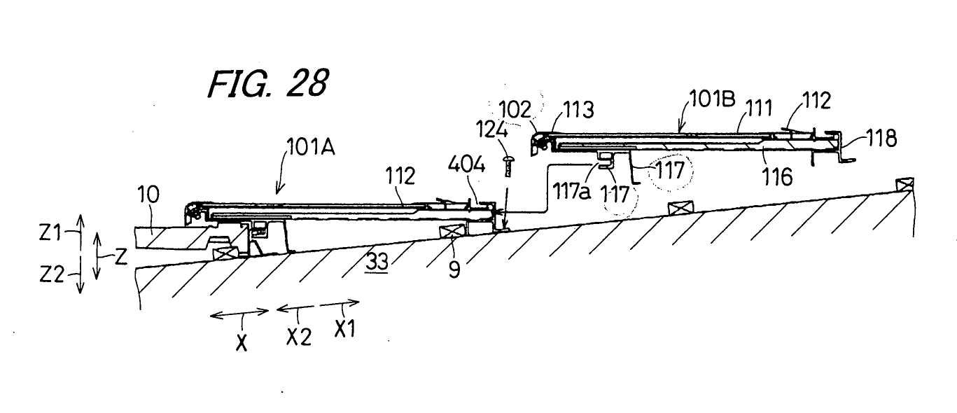

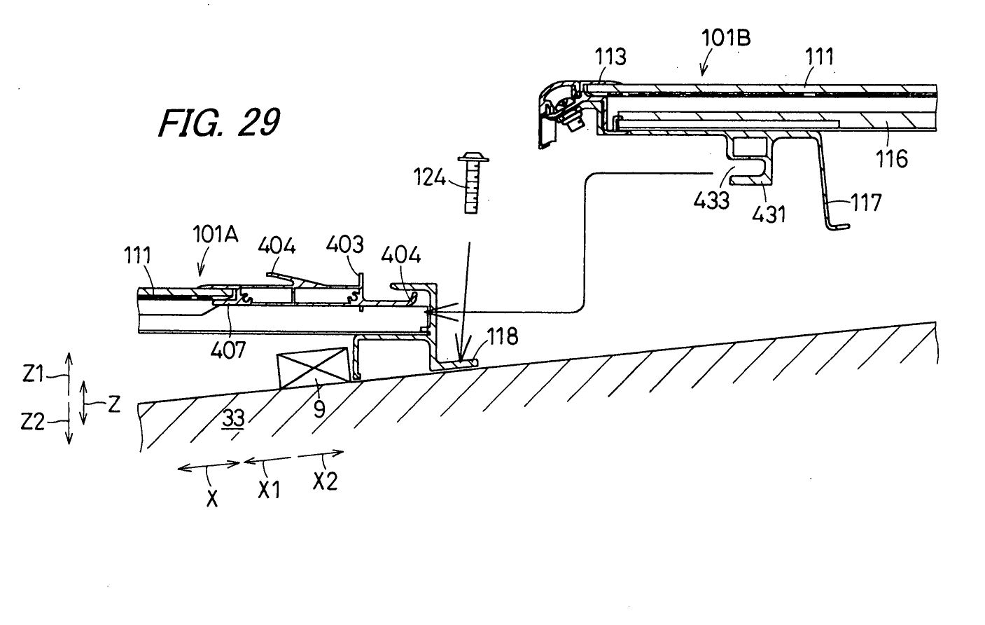

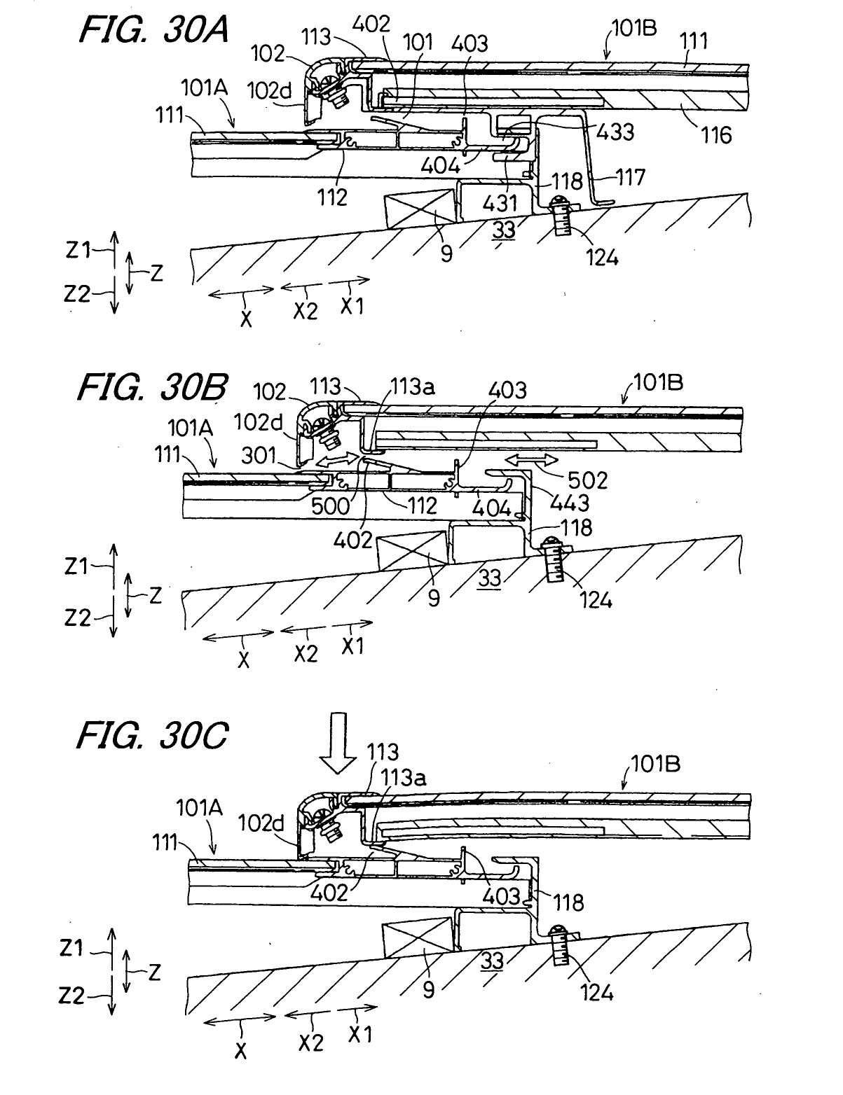

As shown in FIGS. 28 and 29, also in the case of fixing the solar cell modules 101, similarly, an engaging member 404 of the ridge side long side frame 112 of a solar cell module 101A on the eaves side is contained into an engaging recess portion 433 formed by a displacement blocking portion 431 of the eaves side fixing metal piece 117 of a the solar cell module 101B on the ridge side, and the engaging portion 404 is pinched by the displacement blocking portion 431. Thereby, the solar cell modules are fixed in a tile overlapping shape, i. e., in such a manner that a ridge side end portion of an eaves side solar cell module is arranged below an eaves side end portion of a ridge side solar cell module, as shown in FIG. 30A. At this occasion, although the solar cell module 101B on the ridge side is arranged to cover an upper portion of the ridge side long side frame 112 of the solar cell module 101A on the eaves side, the solar cell module 101B is installed to provide a clearance 500 which is not closed by the solar cell module 101A and the solar cell module 101B by the casing 151.

Further, along an entire length of the eaves side face 102d of the solar cell module 101B on the ridge side, an opening 501 to the clearance is provided.

As shown in FIGS. 20 to 23, two pieces of casings 151 are attached to the solar cell portion 150, ventilation by a ventilating path 502 can be carried out as shown by an arrow since a portion which is not provided with the eaves side fixing metal piece 117 has a section as shown in FIG. 30B, and humidity by entered rain or dew condensation and heat below the tile generated in summer time or the like can be exhausted through a clearance between the first frame upper portion stopper projection 402, and the second frame upper portion stopper projection 403 of the solar cell module 101 and the frame lower portion supporting portion 113a of the solar cell module 101B on the ridge side.

Further, the first frame upper portion stopper projection 402 is constituted by a structure of being inclined to the eaves side and is constituted by a structure in which rain water is difficult to flow thereinto. Further, also with regard to rain water entered by riding over the first frame upper portion stopper projection 402, the rain water is dammed by the second frame upper portion stopper projection 403 and is exhausted without being stayed on the rear side of the first frame upper portion projection stopper 402 by an inclined structure of the first frame stopper upper portion projection 402 inclined to the eaves side.

Meanwhile, in the case of such a structure, when a load by a load of fallen snow or by an operator riding over the module is applied to a portion which is not provided with the casing 151, there is a concern that the eaves side of the solar cell module 101B on the ridge side is bent downwardly, thereby, the eaves side long side frame 113 is deformed not to recover and the frame cover 102 is detached, or a portion of storing rain water is produced by deformation. Hence, as shown in FIG. 30C, the frame lower portion supporting portion 113a for supporting the load of an eaves side face 102d is provided in a lower portion of the eaves side long side frame 113 of the solar cell module 101B on the ridge side, and when the load is applied, the load is supported by at least one of the frame upper portion stopper projections 402 and 403 of the ridge side long side frame 112 of the solar cell module 101A on the eaves side, and the solar cell module 101B and the load applied thereto are supported by the ridge side long side frame 112 of the solar cell module 101A on the eaves side.

By constituting in this way, even when the load is applied by the operator riding on the solar cell module 101, by slight movement of the eaves side long side frame 113 of the solar cell module, the load is supported by the frame upper portion stopper projections 402 and 403 and therefore, the frame of four sides of the solar cell module 101 is difficult to deform. The same goes with an average load of fallen snow or the like.

Here, it is important that the stopper projection 402 and 403 is provided on the ridge side with respect to the eaves side face 102d of the solar cell module 101B on the ridge side. Further, in the embodiment, although the stopper projections 402 and 403 are provided in the solar cell module 101A on the eaves side, the stopper projection 125 may be provided in the solar cell module 101B on the ridge side.

Further, even when the load is applied, since no situation that by pushing the frame cover 102 on the solar cell module 101A on the eaves side, a surface thereof is scraped occurs, the appearance of the solar cell module can be protected. Further, both of the frame upper portion stopper projection 402 and 403, and the frame lower portion supporting portion 113a which are the supporting portions for supporting the load, are ridge portions of a rain baffle for preventing rain water from entering provided over the entire length of the eaves side face 102d and in which rain water is not stored and therefore, even when a surface treatment or the like is exfoliated by the load, there is no danger of effecting an influence on the product quality. Further, the contact portions of the solar cell module 101 are separated from each other in normal state and therefore, creak sound or the like is not emitted.

Next, an explanation will be given of a method of removing the solar cell module for maintenance or the like.

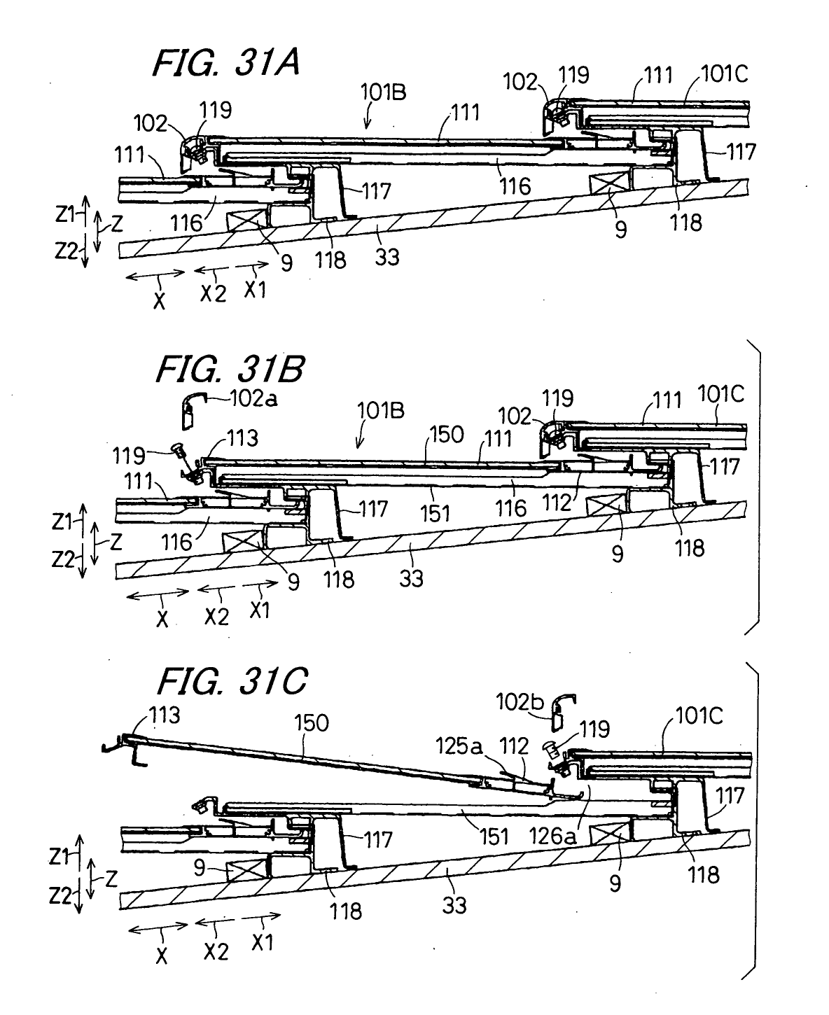

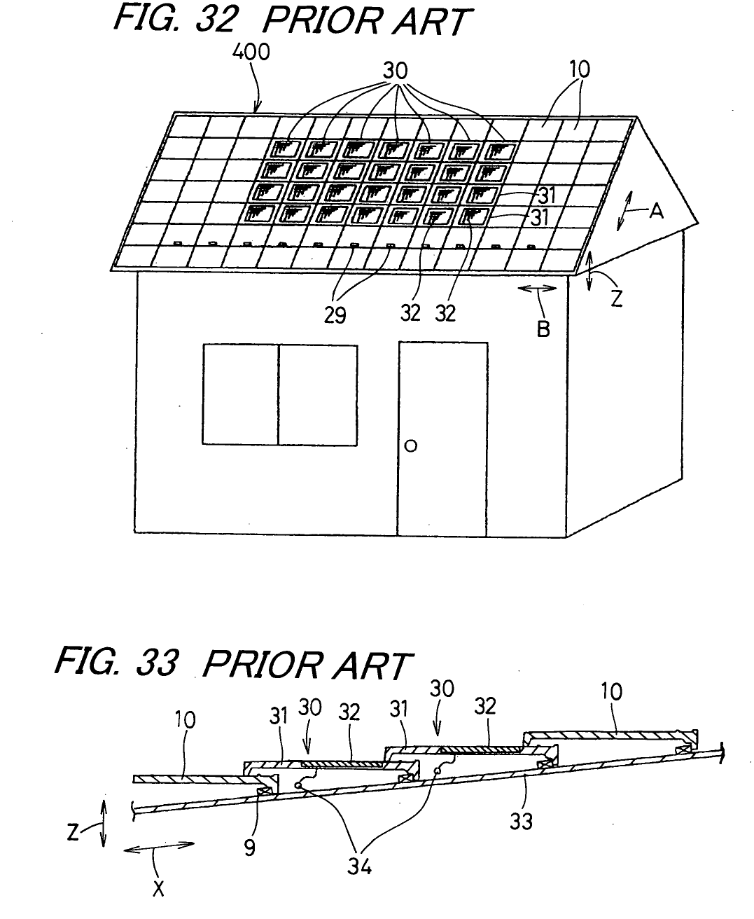

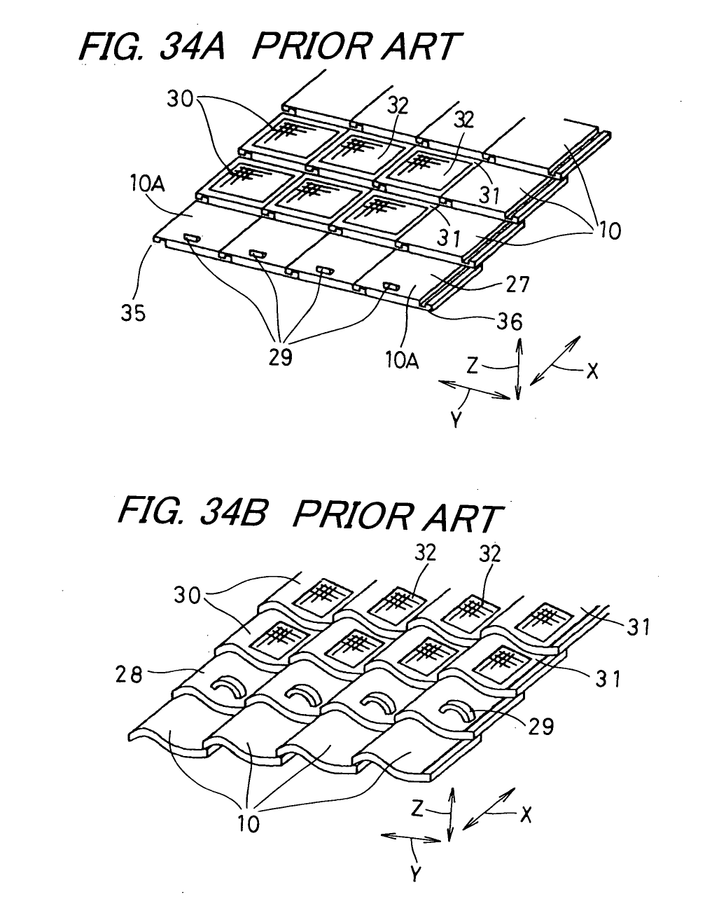

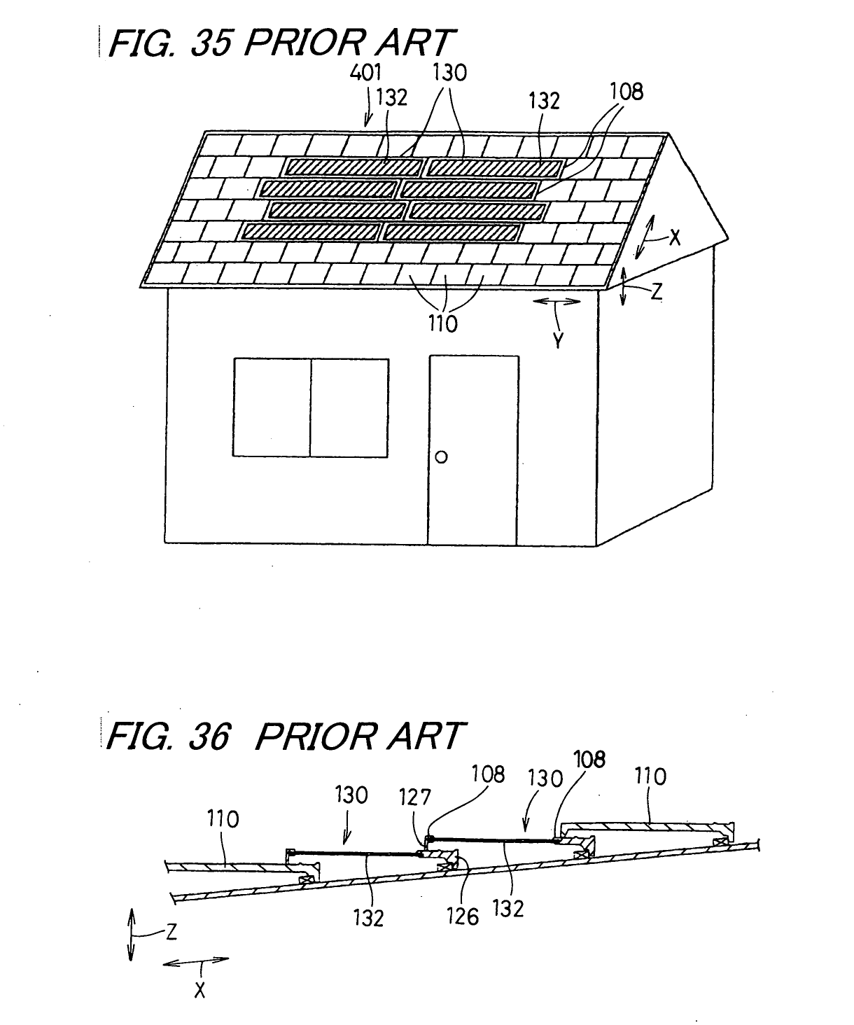

As shown in FIG. 31A, when the solar cell module 101B finished with installation thereof once is removed, as shown in FIG. 31B, by removing the frame cover 102a of the solar cell module 101 to be removed, the fastening screw 119 coupling the solar cell portion 150 and the casing 151 can easily be removed and as shown in FIG. 31C, by also removing a frame cover 102b of a solar cell module 101C arranged on the ridge side with respect to the solar cell module 101B to be removed, only the solar cell portion 150 can be removed. At this occasion, by forming the clearance between the first frame upper portion stopper projection 402 of the solar cell module 101B to be removed and the frame lower portion supporting portion 113a of the solar cell module 101C arranged on the ridge side with respect to the solar cell module 101B to be removed, the solar cell portion 150 can be simply and conveniently removed without being engaged or damaged. Further, the fitting of the solar cell modules to each other can be easily carried out by a reverse procedure thereto.

As described above in details, according to the solar cell array 91 constituting the solar cell modules 101 in the tile overlapping shape, there are provided projections or supporting portions coupled with the portion of overlapping the solar cell module 101A on the eaves side and the solar cell module 101B on the ridge side, the clearance which is not closed in normal state is provided between the projections, ventilating performance is ensured in normal state, and the load is supported by the projection when the load is applied. Therefore, humidity and heat on the rear side of the tile are not stored, creak or wear of the tile overlapping portion is not brought about, and further, the solar cell module can easily be removed in maintenance or the like.

Further, the above-described solar cell module 101 is provided with one or more projections for rain baffle on the ridge side frame upper portion, one or more projections thereamong receive a load receiving portion of the solar cell module at the upper stage. Thereby, a rain baffle structure capable of dealing with blowing of rain can be constituted.

Although the embodiments of the invention have been exemplified as described above, the invention is not limited to the embodiments but naturally can be constituted by an arbitrary mode so far as the object of the invention is not deviated. For example, a solar cell module which has both features of the solar cell module 1 shown in FIGS. 1 to 4 and the solar cell module 101 shown in FIGS. 20 to 23 belongs to the invention as well.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A solar cell module for covering a roof board in cooperation with a tile by being arranged at a roof face along with the tile, the solar cell module comprising:
a positioning member positioned to the tile or another solar cell module in a state of being arranged at the roof board; and
a power generating member having a power generating function and attachably and detachably mounted to the positioning member.

2. The solar cell module of claim 1, wherein the positioning member includes a displacement blocking portion for blocking displacement to a lower side in a state of being arranged at the roof board.

3. The solar cell module of claim 1, wherein the positioning member supports each end portion of the power generating member in a state of being arranged at the roof board.

4. The solar cell module of claim 1, wherein the positioning member includes a guiding portion for guiding the power generating member to a predetermined mounting position.

5. The solar cell module of claim 1, further comprising:
a connecting member for attachably and detachably fixing a power-generating-member-side fixing portion provided in the power generating member and a positioning-member-side fixing portion provided in the positioning member in a state of mounting the power generating member to the positioning member; and
a cover member covering the connecting member and attachably and detachably mounted to the power-generating-member-side fixing portion or the positioning-member-side fixing portion.

6. The solar cell module of claim 5, wherein the cover member includes:
a main body portion;
a movable portion displaceably provided to the main body portion; and
resilient force generating means for exerting a resilient force directed to one side in a predetermined displacing direction to the movable portion,
wherein in a state in which the movable portion is disposed on the one side in the displacing direction, the movable portion is engaged with the positioning member or the power generating member and the cover member is mounted to the positioning member or the power generating member.

7. The solar cell module of claim 1, wherein the power generating member having a power generating function has two end portions opposed to each other, an eaves side frame is provided at one end portion of the power generating member, and a ridge side frame is provided at another end portion of the power generating member, a cover member capable of being brought into contact with a ridge side frame of another solar cell module is attachably and detachably attached to the eaves side frame, the eaves side frame is provided with an eaves side frame engaging member which engages with the cover member, and the cover member is provided with a cover member engaging member which engages with the eaves side frame engaging member and an elastic member brought into contact with the eaves side frame engaging member to press.

8. The solar cell module of claim 5, wherein a snow guard portion is provided in the cover member.

9. The solar cell module of claim 1, wherein in the solar cell module being installed to overlap a solar cell module at an upper stage and a solar cell module or a tile at a lower stage in such a manner that a ridge side end portion of the solar cell module or the tile at the lower stage is arranged below an eaves side end portion of the solar cell module or the tile at the upper stage, a clearance is provided between the solar cell module at the upper stage and the solar cell module at the lower stage or the tile in a vertical direction, an opening to the clearance is provided along an entire length of an eaves side face of the solar cell module at the upper stage and a ventilating path is constituted by the clearance in a direction orthogonal to the eaves side face.

10. The solar cell module of claim 9, wherein a lower face of the solar cell module at the upper stage is provided with an attaching metal piece for sandwiching a ridge side end portion of the solar cell module at the lower stage or a ridge side end portion of the tile, or an attaching metal piece engaging with a support metal piece fixed to a roof face.

11. The solar cell module of claim 10, wherein a stopper for supporting the solar cell module at the upper stage when an eaves side end portion of the solar cell module at the upper stage is bent downwardly, is provided on a ridge side with respect to the eaves side face.

12. The solar cell module of claim 11, wherein the stopper is a projection provided on the ridge side end portion of the solar cell module at the lower stage or the ridge side end portion of the tile along the entire length of the eaves side face.

13. The solar cell module of claim 12, wherein the projection is inclined to an eaves side.

14. The solar cell module of claim 9, wherein an attachable and detachable cover member is hung at the eaves end portion of the solar cell module at the upper stage.

15. The solar cell module of claim 1, wherein in a state of being arranged to the roof board and positioned to the tile or other solar cell module, a clearance is formed in a vertical direction between the solar cell module and a tile or another solar cell module adjacent thereto in the vertical direction, and the clearance communicates with an outside space on an upper side of the roof.

16. The solar cell module of claim 15, wherein openings continuing from the clearance to outside space are respectively formed at a lower side end portion of the solar cell module and an upper side end portion of the solar cell module and the respective openings are formed over an entire length in an extending direction of the lower side end portion and the upper side end portion.

17. The solar cell module of claim 16, wherein the clearance forms a ventilating path extending substantially linearly from the opening on the lower side to the opening on the upper side.

18. The solar cell module of claim 1, wherein a stopper for preventing deformation of the solar cell module on an upper side in a state of arranging the solar cell module on the roof board and bending the solar cell module on the upper side downwardly.

19. The solar cell module of claim 18, wherein the stopper faces an end face on an eaves side of the solar cell module on the upper side.

20. The solar cell module of claim 19, wherein the stopper is formed over an entire length in the extending direction of the upper side end portion of the solar cell module.

21. The solar cell module of claim 20, wherein the stopper inclinedly extends to project on the upper side with the proximity to an eaves.

22. A solar cell array comprising:
a plurality of the solar cell modules of claim 1, overlapping each other in such a manner that a ridge side end portion of an eaves side solar cell module is arranged below an eaves side end portion of a ridge side solar cell module and the respective solar cell modules being electrically connected to each other.
